(19) United States
(12) Patent Application Publication
(10) Pub. No.: US 2026/0301677 A1
(43) Pub. Date: Oct. 1, 2026

(54) SHIFT REGISTER UNIT, DISPLAY DRIVING CIRCUIT, AND DISPLAY PANEL

(71) Applicants: Hefei BOE Joint Technology Co., Ltd., Hefei, Anhui (CN); BOE Technology Group Co., Ltd., Beijing (CN); Beijing BOE Technology Development Co., Ltd., Beijing (CN)

(72) Inventors: Zhidong Yuan, Beijing (CN); Yongqian Li, Beijing (CN)

(73) Assignees: Hefei BOE Joint Technology Co., Ltd., Hefei, Anhui (CN); BOE Technology Group Co., Ltd., Beijing (CN); Beijing BOE Technology Development Co., Ltd., Beijing (CN)

(21) Appl. No.: 18/877,517

(22) PCT Filed: Aug. 12, 2024
(86) PCT No.: PCT/CN2024/111418

§ 371 Date: Dec. 20, 2024

(30) Foreign Application Priority Data
Sep. 27, 2023 (CN) 202311271880.1

(51) Int. Cl. G09G 3/3266; G09G 3/3233; G11C 19/28

(52) U.S. Cl. CPC G09G 3/3266; G09G 3/3233; G11C 19/28; G09G 2300/0408; G09G 2300/0819; G09G 2300/0852; G09G 2300/0861; G09G 2310/0286; G09G 2310/08

(57) ABSTRACT

A shift register unit, a display driving circuit, and a display panel are provided. The shift register unit includes: an input circuit, a pull-up circuit, a pull-down circuit, a cascaded output circuit, and a signal output circuit. The signal output circuit is coupled to K clock signal terminals and K output signal terminals, and configured to generate K driving signals. At least one output unit of the signal output circuit is configured to provide a signal of one of the power signal terminal and corresponding clock signal terminal to corresponding output signal terminal, under control of the pull-up and pull-down nodes; and at least another output unit of the signal output circuit is configured to provide a signal of one of the reference signal terminal and corresponding clock signal terminal to corresponding output signal terminal, under control of the pull-up and pull-down nodes.

This application claims the benefit of priority to Chinese Patent Application No. 2023112718801, filed on Sep. 27, 2023. The entire contents of this application are hereby incorporated herein by reference.

### TECHNICAL FIELD

The present disclosure relates to a field of display technology, and in particular, to a shift register unit, a display driving circuit, and a display panel.

### BACKGROUND

A display panel is provided with multiple sub-pixels and a driving circuit for driving the sub-pixels. Usually, multiple driving signals are used to drive a single sub-pixel, each of the driving signals is provided by a separate driving circuit. However, this design is not conducive to narrow bezels and low cost.

### SUMMARY

According to an aspect of the present disclosure, a shift register unit is provided, and the shift register unit includes: an input circuit coupled to an input signal terminal of the shift register unit, and configured to input a signal of the input signal terminal to a pull-up node; a pull-up circuit coupled to the input signal terminal and a pull-down node of the shift register unit, and configured to pull up a potential of the pull-down node based on a potential of the input signal terminal; a pull-down circuit coupled to the pull-up node and the pull-down node, and configured to pull down the potential of the pull-down node based on a potential of the pull-up node; a cascaded output circuit coupled to the pull-up node, the pull-down node, a power signal terminal of the shift register unit, a reference signal terminal of the shift register unit, and a cascaded output terminal of the shift register unit, and configured to provide a signal of one of the power signal terminal and the reference signal terminal to the cascaded output terminal under control of the pull-up node and the pull-down node; and a signal output circuit coupled to K clock signal terminals of the shift register unit and K output signal terminals of the shift register unit, and configured to generate K driving signals for driving a sub-pixel, wherein signals output from at least two of the K output signal terminals have different duty cycles, and the K driving signals include a gate driving signal and a light-emitting control signal, and wherein K is an integer greater than 1, wherein the signal output circuit includes K output units, with a k^{th} output unit being coupled to the pull-up node, the pull-down node, a k^{th} clock signal terminal, and a k^{th} output signal terminal, where 1<k≤K; wherein at least one of the K output units is further coupled to the power signal terminal, and is configured to provide a signal of one of the power signal terminal and the clock signal terminal coupled to the at least one of the K output units to the output signal terminal coupled to the at least one of the K output units, under control of the pull-up node and the pull-down node; and wherein at least another of the K output units is further coupled to the reference signal terminal, and is configured to provide a signal of one of the reference signal terminal and the clock signal terminal coupled to the at least another of the K output units to the output signal terminal coupled to the at least another of the K output units, under control of the pull-up node and the pull-down node.

For example, each of the K output units includes a first output sub-circuit and a second output sub-circuit, each of the first output sub-circuit and the second output sub-circuit has a control terminal, an input terminal, and an output terminal and is configured to provide a signal of the input terminal to the output terminal under control of the control terminal; and wherein, for each of the K output units, the control terminal of the first output sub-circuit is coupled to the first pull-up node, the input terminal of the first output sub-circuit is coupled to the clock signal terminal corresponding to the output unit, and the output terminal of the first output sub-circuit is coupled to the output signal terminal corresponding to the output unit; and the control terminal of the second output sub-circuit is coupled to the pull-down node, the input terminal of the second output sub-circuit is coupled to the power signal terminal or the reference signal terminal, and the output terminal of the second output sub-circuit is coupled to the output signal terminal corresponding to the output unit.

For example, the first output sub-circuit includes a first transistor and a first capacitor, a gate of the first transistor serves as the control terminal of the first output sub-circuit, a first electrode of the first transistor serves as the input terminal of the first output sub-circuit, and a second electrode of the first transistor serves as the output terminal of the output sub-circuit, a first electrode of the first capacitor is coupled to the gate of the first transistor, and a second electrode of the first capacitor is coupled to the second electrode of the first transistor; and the second output sub-circuit includes a second transistor, a gate of the second transistor serves as the control terminal of the second output sub-circuit, a first electrode of the second transistor serves as the input terminal of the second output sub-circuit, and a second electrode of the second transistor serves as the output terminal of the second output sub-circuit.

For example, one of the K clock signal terminals is electrically coupled to the power signal terminal.

For example, the cascaded output circuit includes: a first cascaded sub-circuit coupled to the pull-up node, the power signal terminal, and the cascaded output terminal, and configured to provide a signal of the power signal terminal to the cascaded output terminal under control of the pull-up node; and a second cascaded sub-circuit coupled to the pull-down node, the reference signal terminal, and the cascaded output terminal, and configured to provide a signal of the reference signal terminal to the cascaded output terminal under control of the pull-down node.

For example, the first cascaded sub-circuit includes a third transistor and a second capacitor, a gate of the third transistor is coupled to the pull-up node, a first electrode of the third transistor is coupled to the power signal terminal, a second electrode of the third transistor is coupled to the cascaded output terminal, a first electrode of the second capacitor is coupled to the gate of the third transistor, and a second electrode of the second capacitor is coupled to the second electrode of the third transistor; and the second cascaded sub-circuit includes a fourth transistor and a third capacitor, a gate of the fourth transistor is coupled to the pull-down node, a first electrode of the fourth transistor is coupled to the reference signal terminal, a second electrode of the fourth transistor is coupled to the cascaded output terminal, a first electrode of the third capacitor is coupled to the gate of the fourth transistor, and a second electrode of the third capacitor is coupled to the second electrode of the fourth transistor.

For example, the second cascaded sub-circuit further includes a fifth transistor and a sixth transistor, the second electrode of the fourth transistor is coupled to the cascaded output terminal through the fifth transistor, wherein a first electrode of the fifth transistor is coupled to the second electrode of the fourth transistor, a second electrode of the fifth transistor is coupled to the cascaded output terminal, and a gate of the fifth transistor is coupled to the pull-down node; and a gate of the sixth transistor is coupled to the cascaded output terminal, a first electrode of the sixth transistor is coupled to the power signal terminal, and a second electrode of the sixth transistor is coupled to the pull-up node.

For example, the power signal terminal includes a first power signal terminal and a second power signal terminal, and the reference signal terminal includes a first reference signal terminal and a second reference signal terminal; and wherein the cascaded output circuit is coupled to the first power signal terminal and the first reference signal terminal, and the signal output circuit is coupled to the second power signal terminal and the second reference signal terminal.

For example, the pull-up circuit includes: a first control sub-circuit coupled to the input signal terminal, the power signal terminal, a second control signal terminal of the shift register unit and an intermediate node of the shift register unit, and configured to control a potential of the intermediate node based on the signal of the input signal terminal and a signal of the second control signal terminal; and a second control sub-circuit coupled to the intermediate node, the pull-down node, and a first control signal terminal of the shift register unit, and configured to pull up the potential of the pull-down node based on a signal of the intermediate node and a signal of the first control signal terminal.

For example, the first control sub-circuit includes a seventh transistor and an eighth transistor, a gate of the seventh transistor is coupled to the second control signal terminal, a first electrode of the seventh transistor is coupled to the power signal terminal, a second electrode of the seventh transistor is coupled to the intermediate node, a gate of the eighth transistor is coupled to the input signal terminal, a first electrode of the eighth transistor is coupled to the second control signal terminal, and a second electrode of the eighth transistor is coupled to the intermediate node; and the second control sub-circuit includes a ninth transistor, a tenth transistor and a fourth capacitor, a gate of the ninth transistor is coupled to the intermediate node, a first electrode of the ninth transistor is coupled to the first control signal terminal, a second electrode of the ninth transistor is coupled to a first electrode of the tenth transistor, a gate of the tenth transistor is coupled to the first control signal terminal, a second electrode of the tenth transistor is coupled to the pull-down node, a first electrode of the fourth capacitor is coupled to the gate of the ninth transistor, and a second electrode of the fourth capacitor is coupled to the second electrode of the ninth transistor.

For example, the first control sub-circuit further includes an eleventh transistor and a twelfth transistor, the first electrode of the eighth transistor is coupled to the second control signal terminal through the eleventh transistor, wherein a gate of the eleventh transistor is coupled to the input signal terminal, a first electrode of the eleventh transistor is coupled to the second control signal terminal, and a second electrode of the eleventh transistor is coupled to the first electrode of the eighth transistor; and a gate of the twelfth transistor is coupled to the intermediate node, a first electrode of the twelfth transistor is coupled to the power signal terminal, and a second electrode of the twelfth transistor is coupled to the first electrode of the eighth transistor.

For example, the pull-down circuit includes a thirteenth transistor, a gate of the thirteenth transistor is coupled to the pull-up node, a first electrode of the thirteenth transistor is coupled to the reference signal terminal, and a second electrode of the thirteenth transistor is coupled to the pull-down node.

For example, the input circuit includes a fourteenth transistor, a gate of the fourteenth transistor is coupled to a first control signal terminal of the shift register unit, a first electrode of the fourteenth transistor is coupled to the input signal terminal, and a second electrode of the fourteenth transistor is coupled to the pull-up node.

For example, the input circuit further includes a fifteenth transistor, and the second electrode of the fourteenth transistor is coupled to the pull-up node through the fifteenth transistor, wherein a gate of the fifteenth transistor is coupled to the power signal terminal or the first control signal terminal, a first electrode of the fifteenth transistor is coupled to the second electrode of the fourteenth transistor, and a second electrode of the fifteenth transistor is coupled to the pull-up node.

For example, the shift register unit further includes a reset circuit coupled to the pull-up node, the pull-down node, the power signal terminal, the reference signal terminal, and a reset signal terminal of the shift register unit, and configured to provide a signal of the reference signal terminal to the pull-up node and a signal of the power signal terminal to the pull-down node under control of the reset signal terminal.

For example, the reset circuit includes a sixteenth transistor and a seventeenth transistor, a gate of the sixteenth transistor is coupled to the reset signal terminal, a first electrode of the sixteenth transistor is coupled to the reference signal terminal, and a second electrode of the sixteenth transistor is coupled to the pull-up node; and a gate of the seventeenth transistor is coupled to the reset signal terminal, a first electrode of the seventeenth transistor is coupled to the power signal terminal, and a second electrode of the seventeenth transistor is coupled to the pull-down node.

For example, the reset circuit further includes an eighteenth transistor, and the first electrode of the sixteenth transistor is coupled to the reference signal terminal through the eighteenth transistor, wherein a gate of the eighteenth transistor is coupled to the reset signal terminal, a first electrode of the eighteenth transistor is coupled to the reference signal terminal, and a second electrode of the eighteenth transistor is coupled to the first electrode of the sixteenth transistor.

For example, K=4, for one or two of the K output units, the output unit is configured to provide a signal of one of the power signal terminal and the clock signal terminal coupled to the output unit to the output signal terminal coupled to the output unit under control of the pull-up node and the pull-down node; and for others of the K output units, the output unit is configured to provide a signal of one of the reference signal terminal and the clock signal terminal coupled to the output unit to the output signal terminal coupled to the output unit under control of the pull-up node and the pull-down node.

For example, K=3, for one of the K output units, the output unit is configured to provide a signal of one of the power signal terminal and the clock signal terminal coupled to the output unit to the output signal terminal coupled to the output unit under control of the pull-up node and the pull-down node, and for others of the K output units, the output unit is configured to provide a signal of one of the reference signal terminal and the clock signal terminal coupled to the output unit to the output signal terminal coupled to the output unit under control of the pull-up node and the pull-down node.

For example, the signal output circuit is configured to generate some or all of the K driving signals for driving a single sub-pixel.

According to another aspect of the present disclosure, a display driving circuit is provided, and the display driving circuit includes: N cascaded shift register units, wherein the shift register unit is the shift register unit as described above, wherein a cascaded output terminal of an nth stage of shift register unit is coupled to an input signal terminal of an (n+i)th stage of shift register unit, where N, n, and i are positive integers, and n<N.

For example, the display driving circuit is configured to receive M sequentially shifted narrow clock signals and M sequentially shifted wide clock signals, a cycle of each of the M narrow clock signals is identical to a cycle of each of the M wide clock signals, and a duty cycle of each of the M narrow clock signals is less than a duty cycle of each of the M wide clock signal, where a ratio of M to K is a positive integer; and the N shift register units are divided into at least one set of shift register units, each set of shift register units includes M cascaded shift register units, and M k1^{th} clock signal terminals of each set of shift register units are configured to receive the M narrow clock signals, respectively; M k2^{th} clock signal terminals of each set of shift register units are configured to receive the M wide clock signals, respectively, where k1 and k2 are positive integers, 1≤k1≤N, 1≤k2<N, and k 1≠k2.

For example, K=4, i=1, M=4; first clock signal terminals of first to fourth stages of shift register units in each set of shift register units are configured to receive a second narrow clock signal, a third narrow clock signal, a fourth narrow clock signal, and a first narrow clock signal, respectively; second clock signal terminals of the first to fourth stages of shift register units in each set of shift register units are configured to receive the first narrow clock signal, the second narrow clock signal, the third narrow clock signal, and the fourth narrow clock signal, respectively; third clock signal terminals of the first to fourth stages of shift register units in each set of shift register units are configured to receive a first wide clock signal, a second wide clock signal, a third wide clock signal, and a fourth wide clock signal, respectively; and fourth clock signal terminals of the first to fourth stages of shift register units in each set of shift register units are configured to receive the third narrow clock signal, the fourth narrow clock signal, the first narrow clock signal, and the second narrow clock signal, respectively.

For example, K=4, i=1, M=4; first clock signal terminals of first to fourth stages of shift register units in each set of shift register units are configured to receive a fourth wide clock signal, a first wide clock signal, a second wide clock signal, and a third wide clock signal, respectively; second clock signal terminals of the first to fourth stages of shift register units in each set of shift register units are configured to receive the second wide clock signal, the third wide clock signal, the fourth wide clock signal, and the first wide clock signal, respectively; third clock signal terminals of the first to fourth stages of shift register units in each set of shift register units are configured to receive the first wide clock signal, the second wide clock signal, the third wide clock signal, and the fourth wide clock signal, respectively; and fourth clock signal terminals of the first to fourth stages of shift register units in each set of shift register units are configured to receive a third narrow clock signal, a fourth narrow clock signal, a first narrow clock signal, and a second narrow clock signal, respectively.

For example, K=3, i=1, M=4; first clock signal terminals of first to fourth stages of shift register units in each set of shift register units are configured to receive a third narrow clock signal, a fourth narrow clock signal, a first narrow clock signal, and a second narrow clock signal, respectively; second clock signal terminals of the first to fourth stages of shift register units in each set of shift register units are configured to receive a second wide clock signal, a third wide clock signal, a fourth wide clock signal, and a first wide clock signal, respectively; and third clock signal terminals of the first to fourth stages of shift register units in each set of shift register units are configured to receive the second narrow clock signal, the third narrow clock signal, the fourth narrow clock signal, and the first narrow clock signal, respectively.

For example, K=4, i=1, M=8; first clock signal terminals of first to fourth stages of shift register units in each set of shift register units are configured to receive eight wide clock signals sequentially shifted from a second wide clock signal, respectively; second clock signal terminals of the first to fourth stages of shift register units in each set of shift register units are configured to receive eight narrow clock signals sequentially shifted from a seventh narrow clock signal, respectively; third clock signal terminals of the first to fourth stages of shift register units in each set of shift register units are configured to receive eight narrow clock signals sequentially shifted from a first narrow clock signal, respectively; and fourth clock signal terminals of the first to fourth stages of shift register units in each set of shift register units are electrically coupled to the power signal terminal and configured to receive a power signal of the power signal terminal.

For example, K=4, i=1, M=16; first clock signal terminals of first to sixteenth stages of shift register units in each set of shift register units are configured to receive sixteen wide clock signals sequentially shifted from a third wide clock signal, respectively; and second clock signal terminals of the first to sixteenth stages of shift register units in each set of shift register units are configured to receive sixteen narrow clock signals sequentially shifted from a fourteenth narrow clock signal, respectively; third clock signal terminals of the first to sixteenth stages of shift register units in each set of shift register units are configured to receive sixteen wide clock signals sequentially shifted from a first wide clock signal, respectively; and fourth clock signal terminals of the first to sixteenth stages of shift register units in each set of shift register units are configured to receive sixteen narrow clock signals sequentially shifted from a first narrow clock signal.

Embodiments of the present disclosure further provide a display panel including a display driving circuit as described above and a plurality of sub-pixels arranged in an array, wherein the display driving circuit is coupled to the plurality of sub-pixels to provide display driving signals to the plurality of sub-pixels.

For example, K output signal terminals of an n^{th} stage of shift register unit are coupled to an n^{th} row of sub-pixels to provide K display driving signals to the n^{th} row of sub-pixels, and the K display driving signals include a gate driving signal and a light-emitting control signal for driving the n^{th} row of sub-pixels.

For example, K1 output signal terminals of an n^{th} stage of shift register unit and K2 output signal terminals of an (n+j)^{th} stage of shift register unit are coupled to an n^{th} row of sub-pixels to provide K display driving signals to the n^{th} row of sub-pixels, where K1+K2=K, and j is an integer greater than 1.

### BRIEF DESCRIPTION OF THE DRAWINGS

FIG. 1A shows a circuit diagram of a pixel circuit according to an embodiment of the present disclosure.

FIG. 1B shows a timing diagram of driving signals of the pixel circuit shown in FIG. 1A.

FIG. 2A shows a circuit diagram of a pixel circuit according to another embodiment of the present disclosure.

FIG. 2B shows a timing diagram of driving signals of the pixel circuit shown in FIG. 2A.

FIG. 3A shows a circuit diagram of a pixel circuit according to another embodiment of the present disclosure.

FIG. 3B shows a timing diagram of driving signals of the pixel circuit shown in FIG. 3A.

FIG. 4 shows a schematic block diagram of a shift register unit according to an embodiment of the present disclosure.

FIG. 5 shows a schematic block diagram of a shift register unit according to another embodiment of the present disclosure.

FIG. 6 shows a circuit diagram of a shift register unit according to an embodiment of the present disclosure.

FIG. 7 shows a circuit diagram of a shift register unit according to another embodiment of the present disclosure.

FIG. 8 shows a circuit diagram of a shift register unit according to another embodiment of the present disclosure.

FIG. 9A shows a schematic diagram of a display driving circuit according to an embodiment of the present disclosure.

FIG. 9B shows a signal timing diagram of the display driving circuit shown in FIG. 9A.

FIG. 10A shows a schematic diagram of a display driving circuit according to another embodiment of the present disclosure.

FIG. 10B shows a signal timing diagram of the display driving circuit shown in FIG. 10A.

FIG. 11A shows a schematic diagram of a display driving circuit according to another embodiment of the present disclosure.

FIG. 11B shows a signal timing diagram of the display driving circuit shown in FIG. 11A.

FIG. 12A shows a schematic diagram of a display driving circuit according to another embodiment of the present disclosure.

FIG. 12B shows a signal timing diagram of the display driving circuit shown in FIG. 12A.

FIGS. 13A and 13B show schematic diagrams of a display driving circuit according to another embodiment of the present disclosure.

FIG. 13C shows a signal timing diagram of the display driving circuit shown in FIGS. 13A and 13B.

FIG. 14 shows a schematic diagram of a display panel according to an embodiment of the present disclosure.

FIG. 15 shows a schematic diagram of a display panel according to another embodiment of the present disclosure.

### DETAILED DESCRIPTION OF EMBODIMENTS

Although the present disclosure is fully described with reference to accompanying drawings containing preferred embodiments of the present disclosure, before describing, it should be understood that those of ordinary skill in the art may modify the disclosure described herein while obtaining the technical effects of the present disclosure. Therefore, it should be understood that the above description is a broad disclosure for those of ordinary skill in the art, and its content is not intended to limit exemplary embodiments described in the present disclosure.

In addition, in the following detailed description, for the convenience of description, many specific details are set forth to provide a comprehensive understanding of embodiments of the present disclosure. However, clearly, one or more embodiments may be implemented without these specific details. In other cases, well-known structures and devices are illustrated to simplify the accompanying drawings.

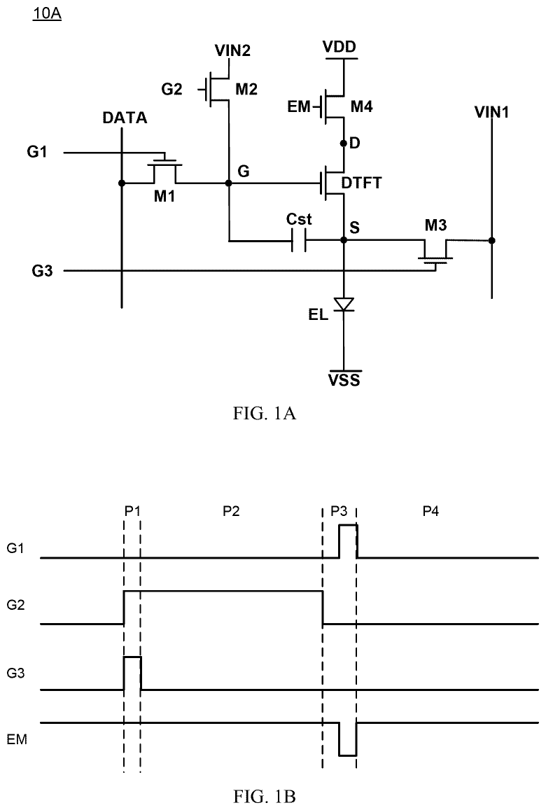

FIG. 1A shows a circuit diagram of a pixel circuit according to an embodiment of the present disclosure.

As shown in FIG. 1A, a pixel circuit 10A of a sub-pixel may include a light-emitting unit EL and a pixel driving circuit for driving the light-emitting unit EL to emit light. According to embodiments of the present disclosure, the pixel driving circuit may include an input sub-circuit, a driving sub-circuit, a compensation sub-circuit, and a light-emitting control sub-circuit. As shown in FIG. 1A, the driving sub-circuit includes a driving transistor DTFT and a capacitor Cst. The input sub-circuit includes a transistor M1. The compensation sub-circuit includes transistors M2 and M3. The light-emitting control sub-circuit includes a transistor M4. The light-emitting unit EL may be a light-emitting diode, such as an organic light-emitting diode OLED. A gate of the transistor M1 receives a first gate driving signal G1, a first electrode of the transistor MI receives a data signal DATA, and a second electrode of the transistor M1 is coupled to a gate G of the driving transistor DTFT. A gate of the transistor M2 receives a second gate driving signal G2, a first electrode of the transistor M2 receives an initial voltage VIN2, and a second electrode of the transistor M2 is coupled to the gate of the driving transistor DTFT. A gate of the transistor M3 receives a third gate driving signal G3, a first electrode of the transistor M3 receives an initial voltage VIN1, and a second electrode of the transistor M3 is coupled to a source of the driving transistor DTFT. A gate of the transistor M4 receives a light-emitting control signal EM, a first electrode of the transistor M4 receives a power supply voltage VDD, and a second electrode of the transistor M4 is coupled to a drain D of the driving transistor DTFT. The source S of the driving transistor DTFT is coupled to a first electrode of the light-emitting unit EL, and a second electrode of the light-emitting unit EL receives a reference voltage VSS.

The driving signals of the pixel circuit in the above embodiment include the first gate driving signal G1, the second gate driving signal G2, the third gate driving signal G3, and the light-emitting control signal EM. That is, the pixel circuit emits light under control of these driving signals. The following provides a detailed description with reference to FIG. 1B.

As shown in FIG. 1B, in a period P1, the first gate driving signal G1 is at low level, the second gate driving signal G2 and the third gate driving signal G3 are at high level, so that the transistors M2 and M3 are turned on, thereby providing the initial voltage VIN2 to the gate G of the driving transistor DTFT and the initial voltage VIN1 to the source S of the driving transistor DTFT.

In a period P2, the third gate driving signal G3 is switched to low level. The transistor M3 is turned off, and the source S of the driving transistor DTFT is charged until the potential difference between the gate G and source S of the driving transistor DTFT is equal to the threshold voltage of the driving transistor DTFT, thereby achieving threshold voltage compensation.

In a period P3, the second gate driving signal G2 is switched to low level, the first gate driving signal G1 is switched to high level, and the light-emitting control signal EM is switched to low level. The transistors M2 and M4 are turned off, and the transistor M1 is turned on, so that the data signal DATA is written into the gate G of the driving transistor DTFT.

In a period P4, the first to third gate driving signals G1, G2, and G3 are at low level, and the light-emitting control signal EM is at high level. The transistor M4 is turned on, and the driving transistor DTFT generates a driving current under control of the data signal at the gate G, in order to drive the light-emitting unit EL to emit light. Thus, the display driving of the pixel circuit is completed.

In the example shown in FIG. 1B, the light-emitting control signal EM is kept at high level in the periods P1 to P2, and the transistor M4 is in ON state. However, embodiments of the present disclosure are not limited to this. It is also possible for the light-emitting control signal EM to be kept at low level or switch between high and low levels in the periods P1 to P2, as long as it does not affect the light-emitting driving.

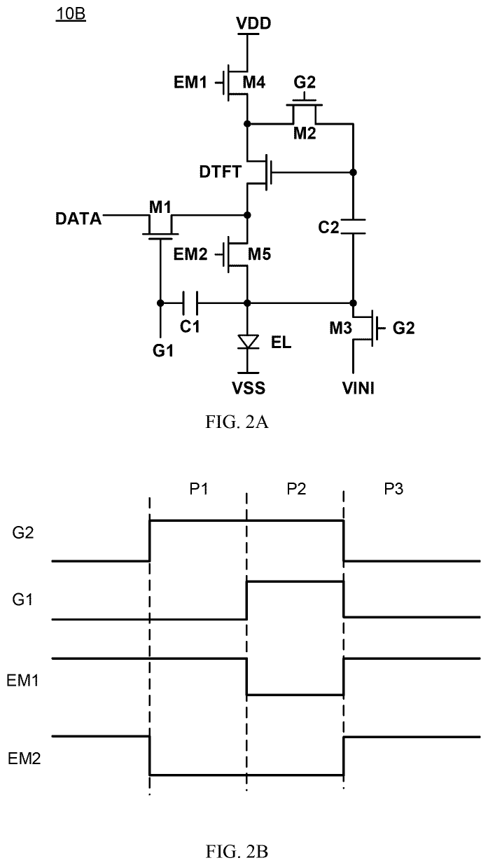

FIG. 2A shows a circuit diagram of a pixel circuit according to another embodiment of the present disclosure.

A pixel circuit 10B shown in FIG. 2A also includes a light-emitting unit EL and a pixel driving circuit for driving the light-emitting unit EL to emit light. The pixel driving circuit may include an input sub-circuit, a driving sub-circuit, a compensation sub-circuit, and a light-emitting control sub-circuit. In the example shown in FIG. 2A, the input sub-circuit includes a transistor M1. The driving sub-circuit includes a driving transistor DTFT and a capacitor C2. The compensation sub-circuit includes transistors M2 and M3 and a capacitor C1. The light-emitting control sub-circuit includes transistors M4 and M5.

A gate of the transistor M1 receives a first gate driving signal G1, a first electrode of the transistor M1 receives a data signal DATA, and a second electrode of the transistor M1 is coupled to a source of the driving transistor DTFT. A gate of the transistor M2 receives a second gate driving signal G2, a first electrode the transistor M2 is coupled to a drain of driving transistor DTFT, and a second electrode of the transistor M2 is coupled to a gate of driving transistor DTFT. A gate of the transistor M3 receives a second gate driving signal G2, and a first electrode of the transistor M3 receives an initial voltage VINI. A first electrode of the capacitor C2 is coupled to the gate of the driving transistor DTFT, and a second electrode of the capacitor C2 is coupled to a second electrode of the transistor M3. A first electrode of the capacitor C1 receives the first gate driving signal G1, and a second electrode of the capacitor C1 is coupled to a first electrode of the light-emitting unit EL. A gate of the transistor M4 receives a first light-emitting control signal EM1, a first electrode of the transistor M4 receives a power supply voltage VDD, and a second electrode of the transistor M4 is coupled to a drain of the driving transistor DTFT. A gate of the transistor M5 receives a second light-emitting control signal EM2, a first electrode of the transistor M5 is coupled to the source of the driving transistor DTFT, a second electrode of the transistor M5 is coupled to the first electrode of the light-emitting unit EL. A second electrode of the light-emitting unit EL is coupled to a reference voltage VSS.

The driving signals of the pixel circuit in the above embodiment include the first gate driving signal G1, the second gate driving signal G2, the first light-emitting control signal EM1, and the second light-emitting control signal EM2. That is, the pixel circuit emits light under control of these driving signals. The following provides a detailed description with reference to FIG. 2B.

As shown in FIG. 2B, in a period P1, the first gate driving signal G1 and the second light-emitting control signal EM2 are at low level, and the second gate driving signal G2 and the first light-emitting control signal EM1 are at high level. The transistors M2, M3, and M4 are turned on, so that the initial voltage VINI is written into the first electrode of the light-emitting unit EL, and the power supply voltage VDD is written into the gate of the driving transistor DTFT.

In a period P2, the first gate driving signal G1 is switched to high level, and the first light-emitting control signal EM1 is switched to low level. The transistor M1 is turned on, so as to write the data signal DATA to the drain S of the driving transistor DTFT. The transistors M4 and M5 are in OFF state, thereby achieving threshold voltage compensation of the driving transistor DTFT.

In a period P3, the first gate driving signal G1 and the second gate driving signal G2 are switched to low level, and the first light-emitting control signal EM1 and the second light-emitting control signal EM2 are switched to high level. The transistors M1 to M3 are turned off, the transistors M4 and M5 are turned on, and the driving transistor DTFT generates a driving current based on the voltage of the gate of the driving transistor DTFT, thereby driving the light-emitting unit EL to emit light.

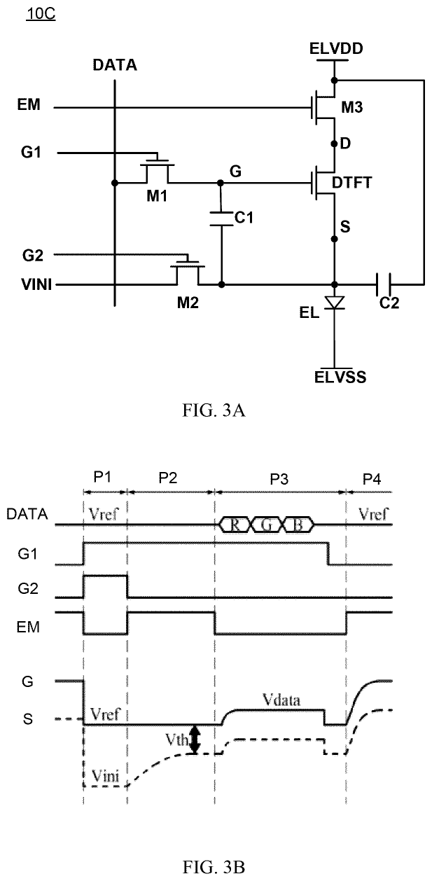

FIG. 3A shows a circuit diagram of a pixel circuit according to another embodiment of the present disclosure.

A pixel circuit 10C shown in FIG. 3A also includes a light-emitting unit EL and a pixel driving circuit for driving the light-emitting unit EL to emit light. The pixel driving circuit may include an input sub-circuit, a driving sub-circuit, a compensation sub-circuit, and a light-emitting control sub-circuit. In the example shown in FIG. 3A, the input sub-circuit includes a transistor M1. The driving sub-circuit includes a driving transistor DTFT and a capacitor C1. The compensation sub-circuit includes a transistor M2 and a capacitor C2. The light-emitting control sub-circuit includes a transistor M3. A gate of the transistor M1 receives a first gate driving signal G1, a first electrode of the transistor M1 receives a data signal DATA, and a second electrode of the transistor M1 is coupled to a gate G of the driving transistor DTFT. A gate of the transistor M2 receives a second gate driving signal G2, a first electrode of the transistor M2 receives an initial voltage VINI, and a second electrode of the transistor M2 is coupled to a source S of the driving transistor DTFT. A gate of the transistor M3 receives a light-emitting control signal EM, a first electrode of the transistor M3 receives a power supply voltage ELVDD, and a second electrode of the transistor M3 is coupled to a drain D of the driving transistor DTFT. A first electrode of the capacitor C1 is coupled to a gate of the driving transistor DTFT, and a second electrode of the capacitor C1 is coupled to a drain S of the driving transistor DTFT. A first electrode of the capacitor C2 is coupled to the drain S of the driving transistor DTFT, and a second electrode of the capacitor C2 receives the power supply voltage ELVDD. A first electrode of the light-emitting unit EL is coupled to the source of the driving transistor DTFT, and a second electrode of the light-emitting unit EL is coupled to a reference voltage ELVSS.

The driving signals of the pixel circuit in the above embodiment include the first gate driving signal G1, the second gate driving signal G2, and the light-emitting control signal EM. That is, the pixel circuit emits light under control of these driving signals. The following provides a detailed description with reference to FIG. 3B.

As shown in FIG. 3B, in a period P1, the first gate driving signal G1 and the second gate driving signal G2 are at high level, the data signal DATA is at reference level, and the light-emitting control signal EM is at low level. The transistors M1 and M2 are turned on, so that the reference level Vref of the data signal DATA is written into the gate G of the driving transistor DTFT, and the initial voltage VINI is written into the source S of the driving transistor DTFT.

In a period P2, the second gate driving signal G2 is switched to low level, and the light-emitting control signal EM is switched to high level. The transistor M1 is kept in ON state, the transistor M2 is turned off, and the potential of the source S of the driving transistor DTFT begins to be increased until the potential difference between the gate G and source S of the driving transistor DTFT is equal to the threshold voltage Vth of the driving transistor DTFT and the driving transistor DTFT is turned off.

In a period P3, the light-emitting control signal EM is switched to low level, and the data signal DATA is switched to data voltage. Different data voltages cause the driving transistor DTFT to generate corresponding driving currents to drive the corresponding light-emitting units EL to display in corresponding grayscales. The light-emitting unit EL may emit one of red light, blue light, or green light, and thus the data voltages shown in FIG. 3B are represented by R, G, and B. The data voltage Vref causes a change in the potential of the gate G of the driving transistor DTFT (gradually increasing in FIG. 3B), and the provision of the capacitor C1 causes a corresponding change in the potential of the source S of the driving transistor DTFT (also increasing in FIG. 3B), in order to maintain the potential difference between the gate G and the source S at Vth.

In a period P4, the light-emitting control signal EM is switched to high level, the first gate driving signal G1 is switched to low level, the transistor M1 is turned off, the transistor M3 is turned on, and the driving transistor DTFT generates a driving current under the voltage of the gate G of the driving transistor DTFT, thereby driving the light-emitting unit EL to emit light.

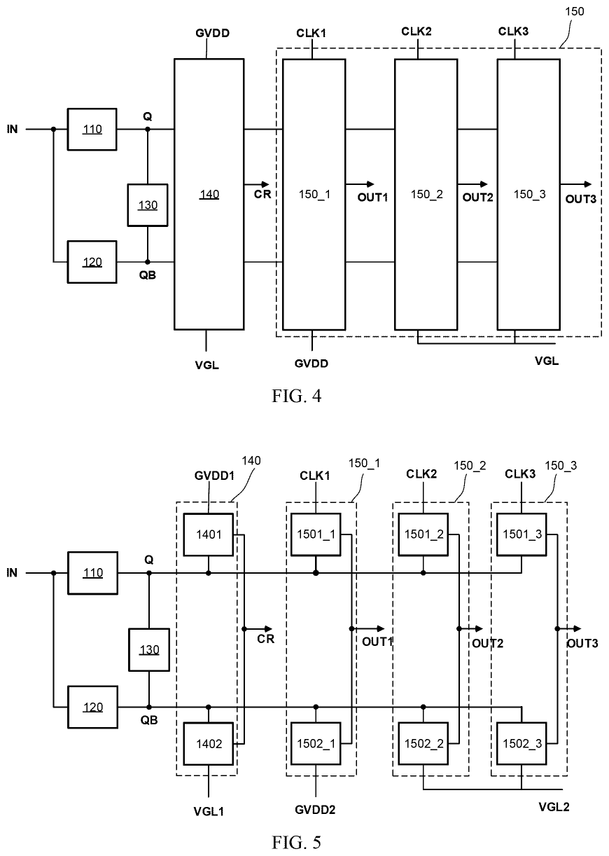

Embodiments of the present disclosure further provide a shift register unit that may provide a gate driving signal and a light-emitting control signal for driving a sub-pixel, such as providing all or some of the required driving signals for the pixel circuit of any of the above embodiments. Although the pixel circuit of the above embodiments is implemented based on N-type transistors, embodiments of the present disclosure are not limited to this. The shift register unit of embodiments of the present disclosure is also applicable to provide required driving signals for sub-pixels with other pixel circuit structures. Embodiments of shift register units are described below with reference to FIGS. 4 to 8.

FIG. 4 shows a schematic block diagram of a shift register unit according to an embodiment of the present disclosure.

As shown in FIG. 4, the shift register unit includes an input circuit 110, a pull-up circuit 120, a pull-down circuit 130, a cascaded output circuit 140, and a signal output circuit 150.

The input circuit 110 is coupled to an input signal terminal IN of the shift register unit. The input circuit 110 may input a signal of the input signal terminal IN to a pull-up node Q.

The pull-up circuit 120 is coupled to the input signal terminal IN and a pull-down node QB of the shift register unit. The pull-up circuit 120 may pull up a potential of the pull-down node QB based on a potential of the input signal terminal IN.

The pull-down circuit 130 is coupled to the pull-up node Q and the pull-down node QB. The pull-down circuit 130 may pull down the potential of the pull-down node QB based on a potential of the pull-up node Q.

The cascaded output circuit 140 is coupled to the pull-up node Q, the pull-down node QB, and a power signal terminal GVDD of the shift register unit, a reference signal terminal VGL of the shift register unit, and a cascaded output terminal CR of the shift register unit. The cascaded output circuit 140 may provide a signal of one of the power signal terminal GVDD and the reference signal terminal VGL to the cascaded output terminal CR under control of the pull-up node Q and the pull-down node QB.

The signal output circuit 150 is coupled to K clock signal terminals of the shift register unit and K output signal terminals of the shift register unit. The signal output circuit 150 may generate K driving signals for driving the sub-pixel, and signals output by at least two of the K output signal terminals have different duty cycles. The K driving signals include a gate driving signal and a light-emitting control signal, where K is an integer greater than 1. For example, the signal output circuit 150 may include K output units coupled to K clock signal terminals, respectively.

In FIG. 4, K=3 is taken as an example for illustration purpose. However, embodiments of the present disclosure are not limited to this. The number of output units may be set as desired.

As shown in FIG. 4, the signal output circuit 150 includes a first output unit 150_1, a second output unit 150_2, and a third output unit 150_3, which are respectively coupled to a first clock signal terminal CLK1, a second clock signal terminal CLK2, and a third clock signal terminal CLK3.

The k^{th} output unit is coupled to the pull-up node Q, the pull-down node QB, the k^{th} clock signal terminal, and the k^{th} output signal terminal, where 1<k≤K. For example, as shown in FIG. 4, the first output unit 150_1 is coupled to the pull-up node Q, the pull-down node QB, the first clock signal terminal CLK1, and the first output signal terminal OUT1. The second output unit 150_2 is coupled to the pull-up node Q, the pull-down node QB, the second clock signal terminal CLK2, and the second output signal terminal OUT2. The third output unit 150_3 is coupled to the pull-up node Q, the pull-down node QB, the third clock signal terminal CLK3, and the third output signal terminal OUT3.

At least one output unit (e.g. the first output unit 150_1) is further coupled to the power signal terminal GVDD, and used to provide the signal of one of the power signal terminal GVDD and the clock signal terminal coupled to the at least one output unit to the output signal terminal coupled to the at least one output unit, under control of the pull-up node Q and the pull-down node QB. As shown in FIG. 4, the first output unit 150_1 is coupled to the pull-up node Q, the pull-down node QB, the power signal terminal GVDD, the first clock signal terminal CLK1, and the first output signal terminal OUT1. The first output unit 150_1 may provide the signal of one of the first clock signal terminal CLK1 and the power signal terminal GVDD to the first output signal terminal OUT1 under control of the pull-up node Q and the pull-down node QB.

At least another output unit (e.g. the second output unit 150_2 and the third output unit 150_3) is further coupled to the reference signal terminal VGL, and used to provide the signal of one of the reference signal terminal VGL and the clock signal terminal coupled to the at least another output unit to the output signal terminal coupled to the at least another output unit, under control of the pull-up node Q and the pull-down node QB. For example, as shown in FIG. 4, the second output unit 150_2 is coupled to the pull-up node Q, the pull-down node QB, the reference signal terminal VGL, the second clock signal terminal CLK2, and the second output signal terminal OUT2. The second output unit 150_2 may provide the signal of one of the second clock signal terminal CLK2 and the reference signal terminal VGL to the second output signal terminal OUT2 under control of the pull-up node Q and the pull-down node QB. The third output unit 150_3 is coupled to the pull-up node Q, the pull-down node QB, the reference signal terminal VGL, the third clock signal terminal CLK3, and the third output signal terminal OUT3. The third output unit 150_3 may provide the signal of one of the third clock signal terminal CLK3 and the reference signal terminal VGL to the third output signal terminal OUT3 under control of the pull-up node Q and the pull-down node QB.

In embodiments of the present disclosure, the shift register unit is provided with a signal output circuit including K output units. Each output unit has an end being coupled to a corresponding clock signal terminal and another end being coupled to a reference signal terminal or a power signal terminal. In this way, the shift register unit may generate multiple display driving signals (such as a gate driving signal and a light-emitting control signal) for driving the sub-pixel, without the need to provide a separate shift register unit for each display driving signal, which is beneficial for the narrow bezel design of the display panel.

FIG. 5 shows a schematic block diagram of a shift register unit according to another embodiment of the present disclosure.

Similar to that shown in FIG. 4, the shift register unit shown in FIG. 5 also includes an input circuit 110, a pull-up circuit 120, a pull-down circuit 130, a cascaded output circuit 140, and a signal output circuit 150. The above description of these circuits also applies to FIG. 5.

Unlike that shown in FIG. 4, the power signal terminal shown in FIG. 5 may include a first power signal terminal GVDD1 and a second power signal terminal GVDD2, and the reference signal terminal may include a first reference signal terminal VGL1 and a second reference signal terminal VGL2. The cascaded output circuit 140 may be coupled to the first power signal terminal GVDD1 and the first reference signal terminal VGL1, and the signal output circuit including K output units 150_1, 150_2, and 150_3 may be coupled to the second power signal terminal GVDD2 and the second reference signal terminal VGL2. By coupling a separate set of signal terminals including a power signal terminal and a reference signal terminal to the signal output circuit, the influence of other circuits on the signal output circuit may be reduced.

As shown in FIG. 5, the cascaded output circuit 140 may include a first cascaded sub-circuit 1401 and a second cascaded sub-circuit 1402.

The first cascaded sub-circuit 1401 is coupled to the pull-up node Q, the power signal terminal (the first power signal terminal GVDD1 shown in FIG. 5), and the cascaded output terminal CR. The first cascaded sub-circuit 1401 may provide the signal of the power signal terminal to the cascaded output terminal CR under control of the pull-up node Q.

The second cascaded sub-circuit 1402 is coupled to the pull-down node QB, the reference signal terminal (the first reference signal terminal VGL1 shown in FIG. 5), and the cascaded output terminal CR. The second cascaded sub-circuit 1402 may provide the signal of the reference signal terminal to the cascaded output terminal CR under control of the pull-down node QB.

In some embodiments, each output unit may include a first output sub-circuit and a second output sub-circuit. For example, as shown in FIG. 5, the first output unit 150_1 includes a first output sub-circuit 1501_1 and a second output sub-circuit 1501_2; the second output unit 1502 includes a first output sub-circuit 1502_1 and a second output sub-circuit 1502_2; and the third output unit 1503 includes a first output sub-circuit 1503_1 and a second output sub-circuit 1503_2.

In some embodiments, each of the first output sub-circuit and the second output sub-circuit includes a control terminal, an input terminal, and an output terminal, and is used to provide the signal of the input terminal to the output terminal under control of the control terminal.

For example, in the first output unit 150_1, the control terminal of the first output sub-circuit 1501_1 is coupled to the first pull-up node Q, the input terminal of the first output sub-circuit 1501_1 is coupled to the first clock signal terminal CLK1, and the output terminal of the first output sub-circuit 1501_1 is coupled to the first output signal terminal OUT1. The control terminal of the second output sub-circuit 1501_2 is coupled to the pull-down node QB, the input terminal of the second output sub-circuit 1501_2 is coupled to the power signal terminal (coupled to the second power signal terminal GVDD2 shown in FIG. 5), and the output terminal of the second output sub-circuit 1501_2 is coupled to the first output signal terminal OUT1.

In the second output unit 150_2, the control terminal of the first output sub-circuit 1502_1 is coupled to the first pull-up node Q, the input terminal of the first output sub-circuit 1502_1 is coupled to the second clock signal terminal CLK2, and the output terminal of the first output sub-circuit 1502_1 is coupled to the second output signal terminal OUT. The control terminal of the second output sub-circuit 1502_2 is coupled to the pull-down node QB, the input terminal of the second output sub-circuit 1502_2 is coupled to the reference signal terminal (coupled to the second reference signal terminal VGL2 shown in FIG. 5), and the output terminal of the second output sub-circuit 1502_2 is coupled to the second output signal terminal OUT2.

Similarly, in the third output unit 150_3, the control terminal of the first output sub-circuit 1503_1 is coupled to the first pull-up node Q, the input terminal of the first output sub-circuit 1503_1 is coupled to the third clock signal terminal CLK3, and the output terminal of the first output sub-circuit 1503_1 is coupled to the third output signal terminal OUT3. The control terminal of the second output sub-circuit 1503_2 is coupled to the pull-down node QB, the input terminal of the second output sub-circuit 1503_2 is coupled to the reference signal terminal (coupled to the second reference signal terminal VGL2 shown in FIG. 5), and the output terminal of the second output sub-circuit 1503_2 is coupled to the third output signal terminal OUT3.

In some embodiments, one of the K clock signal terminals may be electrically coupled to the power signal terminal. For example, in a case that K=4, the fourth clock signal terminal CLK4 may be electrically coupled to the second power signal terminal GVDD2 to receive the second power signal. This is described in detail below.

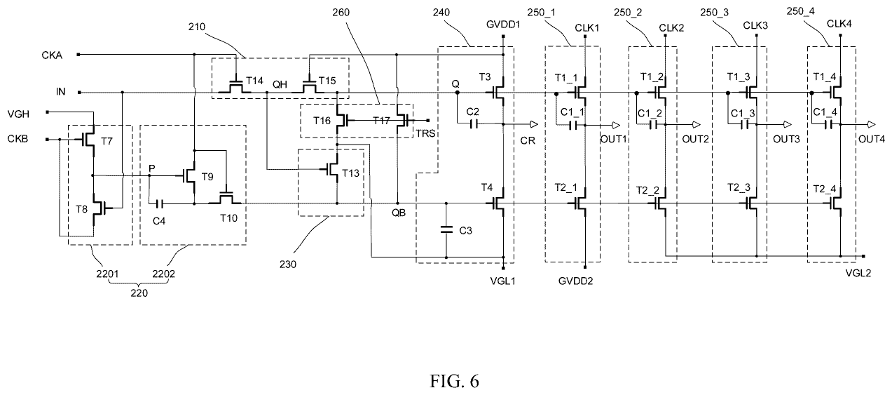

FIG. 6 shows a circuit diagram of a shift register unit according to an embodiment of the present disclosure.

The shift register unit shown in FIG. 6 also includes an input circuit 210, a pull-up circuit 220, a pull-down circuit 230, a cascaded output circuit 240, and a signal output circuit. The above descriptions of the input circuit, pull-up circuit, pull-down circuit, cascaded output circuit, and signal output circuit are also applicable to this embodiment.

As shown in FIG. 6, K=4, the signal output circuit includes a first output unit 250_1, a second output unit 250_2, a third output unit 250_3, and a fourth output unit 250_4.

Each output unit shown in FIG. 6 also includes a first output sub-circuit and a second output sub-circuit. For example, the first output sub-circuit of the first output unit 250_1 includes a first transistor T1_1 and a first capacitor C1_1, and the second output sub-circuit of the first output unit 250_1 includes a second transistor T2_1. Similarly, the first output sub-circuit of the second output unit 250_2 includes a first transistor T1_2 and a first capacitor C1_2, and the second output sub-circuit of the first output unit 250_1 includes a second transistor T2_2. The first output sub-circuit of the third output unit 250_3 includes a first transistor T1_3 and a first capacitor C1_3, and the second output sub-circuit of the first output unit 250 3 includes a second transistor T2_3.

In each output unit, a gate of the first transistor serves as the control terminal of the first output sub-circuit, a first electrode of the first transistor serves as the input terminal of the first output sub-circuit, and a second electrode of the first transistor serves as the output terminal of the first output sub-circuit; a first electrode of the first capacitor is coupled to the gate of the first transistor, and a second electrode of the first capacitor is coupled to the second electrode of the first transistor. A gate of the second transistor serves as the control terminal of the second output sub-circuit, a first electrode of the second transistor serves as the input terminal of the second output sub-circuit, and a second electrode of the second transistor serves as the output terminal of the second output sub-circuit. Taking the first output unit 250_1 as an example, the gate of the first transistor T1_1 is coupled to the pull-up node Q as the control terminal of the first output sub-circuit, the first electrode of the first transistor T1_1 is coupled to the first clock signal terminal CLK1 as the input terminal of the first output sub-circuit, and the second electrode of the first transistor T1_1 is coupled to the first output signal terminal OUT1 as the output terminal of the first output sub-circuit; the first electrode of the first capacitor C1_1 is coupled to the gate of the first transistor T1_1, and the second electrode of the first capacitor C1_1 is coupled to the second electrode of the first transistor T1_1. Again, taking the first output unit 250_1 as an example, the gate of the second transistor T2_1 is coupled to the pull-down node QB as the control terminal of the second output sub-circuit, the first electrode of the second transistor T2_1 is coupled to the second reference signal terminal VGL2 as the input terminal of the second output sub-circuit, and the second electrode of the second transistor T2_1 is coupled to the first output signal terminal OUT1 as the output terminal of the second output sub-circuit. In the second output unit 250_2, third output unit 250_3, and fourth output unit 250_4, the first transistor, second transistor, and second capacitor are coupled in a similar manner and will not be repeated here.

Continuing to refer to FIG. 6, the cascaded output circuit 240 also includes a first cascaded sub-circuit and a second cascaded sub-circuit. The first cascaded sub-circuit includes a third transistor T3 and a second capacitor C2, and the second cascaded sub-circuit includes a fourth transistor T4 and a third capacitor C3. As shown in FIG. 6, a gate of the third transistor T3 is coupled to the pull-up node Q, a first electrode of the third transistor T3 is coupled to the power signal terminal (the first power signal terminal GVDD1 shown in FIG. 6), and a second electrode of the third transistor T3 is coupled to the cascaded output terminal CR. A first electrode of the second capacitor C2 is coupled to the gate of the third transistor T3, and a second electrode of the second capacitor C2 is coupled to the second electrode of the third transistor T3. A gate of the fourth transistor T4 is coupled to the pull-down node QB, a first electrode of the fourth transistor T4 is coupled to the reference signal terminal (the first reference signal terminal VGL1 shown in FIG. 6), and a second electrode of the fourth transistor T4 is coupled to the cascaded output terminal CR. A first electrode of the third capacitor C3 is coupled to the gate of the fourth transistor T4, and a second electrode of the third capacitor C3 is coupled to the second electrode of the fourth transistor T4.

In some embodiments, as shown in FIG. 6, the pull-up circuit 220 may include a first control sub-circuit 2201 and a second control sub-circuit 2202.

The first control sub-circuit 2201 is coupled to the input signal terminal IN, the power signal terminal (as shown in FIG. 6, the power signal terminal is the third power signal terminal VGH, which may also be implemented by other power signal terminals, such as the first power signal terminal GVDD1), a second control signal terminal CKB of the shift register unit, and an intermediate node P of the shift register unit. The first control sub-circuit 2201 may control a potential of the intermediate node P based on a signal of the input signal terminal IN and a signal of the second control signal terminal CKB. As shown in FIG. 6, the first control sub-circuit 2201 includes a seventh transistor T7 and an eighth transistor T8. A gate of the seventh transistor T7 is coupled to the second control signal terminal CKB, a first electrode of the seventh transistor T7 is coupled to the power signal terminal VGH, and a second electrode of the seventh transistor T7 is coupled to the intermediate node P. A gate of the eighth transistor T8 is coupled to the input signal terminal IN, a first electrode of the eighth transistor T8 is coupled to the second control signal terminal CKB, and a second electrode of the eighth transistor T8 is coupled to the intermediate node P.

The second control sub-circuit 2202 is coupled to the intermediate node P, the pull-down node QB, and a first control signal terminal CKA of the shift register unit. The second control sub-circuit 2202 may pull up or pull down a potential of the node QB based on a signal of the intermediate node P and a signal of the first control signal terminal CKB. As shown in FIG. 6, the second control sub-circuit 2202 includes a ninth transistor T9, a tenth transistor T10, and a fourth capacitor C4. A gate of the ninth transistor T9 is coupled to the intermediate node P, a first electrode of the ninth transistor T9 is coupled to the first control signal terminal CKA, a second electrode of the ninth transistor T9 is coupled to a first electrode of the tenth transistor T10, a gate of the tenth transistor T9 is coupled to the first control signal terminal CKA, and a second electrode of the tenth transistor T10 is coupled to the pull-down node QB; a first electrode of the fourth capacitor C4 is coupled to the gate of the ninth transistor T9, and a second electrode of the fourth capacitor C4 is coupled to the second electrode of the ninth transistor T9.

The pull-down circuit 230 may include a thirteenth transistor T13. A gate of the thirteenth transistor T13 is coupled to the pull-up node Q, a first electrode of the thirteenth transistor T13 is coupled to the reference signal terminal (the first reference signal terminal VGL1 shown in FIG. 6), and a second electrode of the thirteenth transistor T13 is coupled to the pull-down node QB.

The input circuit 210 may include a fourteenth transistor T14. A gate of the fourteenth transistor T14 is coupled to the first control signal terminal CKA, a first electrode of the fourteenth transistor T14 is coupled to the input signal terminal IN, and a second electrode of the fourteenth transistor T14 is coupled to the pull-up node Q.

In some embodiments, as shown in FIG. 6, the input circuit may further include a fifteenth transistor T15. In this case, the second electrode of the fourteenth transistor T14 may be coupled to the pull-up node Q through the fifteenth transistor T15. A gate of the fifteenth transistor T15 is coupled to the power signal terminal (the first power signal terminal GVDD1 shown in FIG. 6), a first electrode of the fifteenth transistor T15 is coupled to the second electrode of the fourteenth transistor T14, and a second electrode of the fifteenth transistor T15 is coupled to the pull-up node Q. The fifteenth transistor T15 may have an isolation function. For example, taking the fifteenth transistor T15 being an N-type transistor as an example, the fifteenth transistor T15 is turned off when the potential of the pull-up node Q or node QH is higher than the potential of the gate of the fifteenth transistor (i.e. the potential of the first control signal terminal CKA), so that the pull-up node Q is isolated from the node QH, preventing the output signal from being affected by the high potential of the pull-up node Q.

In some embodiments, as shown in FIG. 6, the shift register unit may further include a reset circuit 260. The reset circuit 260 is coupled to the pull-up node Q, the pull-down node QB, the power signal terminal (the first power signal terminal GVDD1 shown in FIG. 6), the reference signal terminal (the first reference signal terminal VGL1 shown in FIG. 6), and a reset signal terminal TRS of the shift register unit. The reset circuit 260 may provide the signal of the reference signal terminal (first reference signal terminal VGL1) to the pull-up node Q and the signal of the power signal terminal (first power signal terminal GVDD1) to the pull-down node QB under control of the reset signal terminal TRS. In the example shown in FIG. 6, the reset circuit 260 includes a sixteenth transistor T16 and a seventeenth transistor T17. A gate of the sixteenth transistor T16 is coupled to the reset signal terminal TRS, a first electrode of the sixteenth transistor T16 is coupled to the reference signal terminal (first reference signal terminal VGL1), and a second electrode of the sixteenth transistor is coupled to the pull-up node Q. A gate of the seventeenth transistor T17 is coupled to the reset signal terminal TRS, a first electrode of the seventeenth transistor T17 is coupled to the power signal terminal (first power signal terminal GVDD1), and a second electrode of the seventeenth transistor T17 is coupled to the pull-down node QB.

When the shift register unit operates, the input signal terminal IN and the first control signal terminal CKA are at high level, the fourteenth transistor T14 is turned on, and the gate of the fifteenth transistor T15 is turned on under control of the first power signal terminal GVDD1, thereby providing the high level of the input signal terminal IN to the pull-up node Q. The high level of the pull-up node Q causes the first transistors T1_1, T1_2, T1_3, and T1_4 of the output units to be turned on, thereby providing the signals of the clock signal terminals CLK1 to CLK4 respectively coupled to the output units to the corresponding output signal terminals OUT1 to OUT4, and generating four output signals. In this process, the high level of the node QB causes the thirteenth transistor T13 to be turned on, so that the low level of the first reference signal terminal VGL1 is provided to the pull-down node QB, keeping the pull-down node QB at low level.

Next, the input signal terminal IN is switched to low level, so that the eighth transistor T8 is turned off. When the second control signal terminal CKB is at high level, the seventh transistor T7 is turned on, thereby providing the high level of the third power signal terminal VGH to the intermediate node P. The high level of the intermediate node P causes the ninth transistor T9 to be turned on, so as to wait for the arrival of the high level of the first control signal terminal CKA. Afterwards, when the high level of the first control signal terminal CKA arrives, the fourteenth transistor T14 and the fifteenth transistor T15 are turned on, thereby providing the low level of the input signal terminal IN to the pull-up node Q, causing the third transistor T3 and the first transistors T1_1 to T1_4 of the output units to be turned off. The high level of the first control signal terminal CKA also causes the tenth transistor T10 to be turned on, thereby pulling up the pull-down node QB to high level. The high level of the pull-down node QB causes the fourth transistor T4 to be turned on, thereby causing the cascaded output terminal CR to output a low-level signal. The high level of the pull-down node QB also causes the second transistors T2_1, T2_2, T2_3, and T2_4 of the output units to be turned on, so that the first output signal terminal OUT1 outputs a high-level signal, and the second to fourth output signal terminals OUT2 to OUT4 output low-level signals. In this way, the shift register unit generates four output signals, among which the output signal of the first output signal terminal OUT1 may be used as a low-level valid light-emitting control signal and the output signals of the second to fourth output signal terminals OUT2 to OUT4 may be used as high-level valid gate driving signals. After a frame is displayed, all shift register units may be reset. For example, a reset signal at high level is applied to the reset signal terminal TRS of each shift register unit so as to cause the sixteenth transistor T16 and seventeenth transistor T17 of each shift register unit to be turned on. The turned on sixteenth transistor T16 resets the pull-up node Q to the low level of the first reference signal terminal VGL1, and the turned on seventeenth transistor T17 resets the pull-down node QB to the high level of the first power signal terminal GVDD1. In this way, all the output units do not output signals and thus the reset of the shift register unit is achieved.

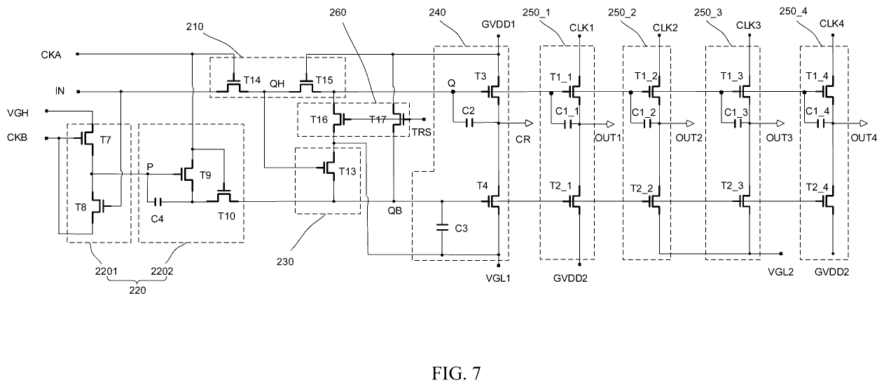

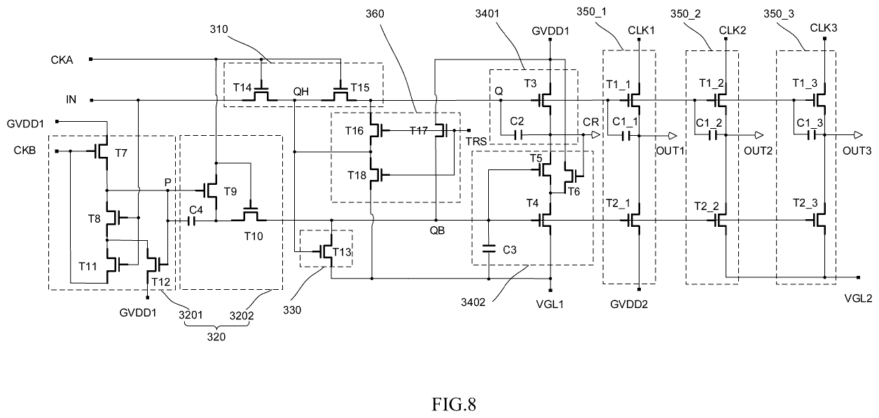

FIG. 7 shows a circuit diagram of a shift register unit according to another embodiment of the present disclosure.

The shift register unit shown in FIG. 7 is similar to that shown in FIG. 6, except that two output units shown in FIG. 7 are coupled to the power signal terminal, and the other two output units are coupled to the reference signal terminal. As shown in FIG. 7, the circuit structures other than the fourth output unit 250_4 are the same as those shown in FIG. 6, and will not be repeated here. The fourth output unit 250_4 is coupled to the fourth clock signal terminal CLK4 and the second power signal terminal GVDD2. When the pull-up node Q is at high level and the pull-down node QB is at low level, the transistor T1_4 is turned on and the transistor T2_4 is turned off, thereby providing the signal of the fourth clock signal terminal CLK4 to the output signal terminal OUT4. When the pull-up node Q is at low level and the pull-down stage QB is at high level, the transistor T1_4 is turned off and the transistor T2_4 is turned on, thereby providing the signal of the second power signal terminal GVDD2 to the output signal terminal OUT4.

The shift register units described above with reference to FIGS. 6 and 7 include four output signal terminals, which may generate four display driving signals, such as the driving signal required by the pixel circuit 10A described above, for driving a single sub-pixel.

FIG. 8 shows a circuit diagram of a shift register unit according to another embodiment of the present disclosure.

Similar to that shown in FIG. 6, the shift register unit shown in FIG. 8 also includes an input circuit 310, a pull-up circuit 320, a pull-down circuit 330, a cascaded output circuit, a signal output circuit, and a reset circuit 360. The difference from FIG. 6 is at least in that K=3 (that is, the signal output circuit includes three output units). In addition, at least one of the pull-up circuit 320, the cascaded output circuit, or the reset circuit 360 in the shift register unit shown in FIG. 8 may be further provided with an anti-leakage structure. For ease of description, detailed description will be made mainly on the differences in the following.

The input circuit 310 includes a fourteenth transistor T14 and a fifteenth transistor T15. Unlike that shown in FIG. 6, a gate of the fifteenth transistor T15 in the input circuit 310 shown in FIG. 8 is coupled to the first control signal terminal CKA. It is also possible to achieve the isolation by coupling the fifteenth transistor T15 in this manner. For example, when the first control signal terminal CKA is at high level, the fifteenth transistor T15 is turned on, thereby causing the high level of the input signal terminal IN to be input into the pull-up node Q through the fourteenth transistor T14 and the fifteenth transistor T15. When the first control signal terminal CKA is at low level, the fifteenth transistor T15 is turned on, thereby isolating the node QH from the pull-up node Q. At this point, even if the fourteenth transistor T14 leaks or the potential of the node QH increases due to other reasons, the potential of the pull-up node Q may be prevented from being affected by the node QH due to the provision of the fifteenth transistor T15.

The pull-up circuit 320 includes a first control sub-circuit 3201 and a second control sub-circuit 3202. The second control sub-circuit 3202 has the same structure as the second control sub-circuit 2202 described above, which will not be repeated here. Unlike that shown in FIG. 6, the first control sub-circuit 3201 includes not only the seventh transistor T7 and the eighth transistor T8, but also the eleventh transistor T11 and the twelfth transistor T12. A first electrode of the eighth transistor T8 is coupled to the second control signal terminal CKB through the eleventh transistor T11. As shown in FIG. 8, a gate of the eleventh transistor T11 is coupled to the input signal terminal IN, a first electrode of the eleventh transistor T11 is coupled to the second control signal terminal CKB, and a second electrode of the eleventh transistor T11 is coupled to the first electrode of the eighth transistor T8. A gate of the twelfth transistor T12 is coupled to the intermediate node P, a first electrode of the twelfth transistor T12 is coupled to the power signal terminal, and a second electrode of the twelfth transistor T12 is coupled to the first electrode of the eighth transistor. By providing the eleventh transistor T11 and the twelfth transistor T12, leakage may be prevented. For example, when the input signal terminal IN is at low level, the intermediate node P is at high level, and the second control signal terminal CKB is at low level, if the eleventh transistor T11 and the twelfth transistor T12 are not provided, the following situation will occur: the eighth transistor T8 will be in OFF state, but there is a large voltage difference between the first and second electrodes of the eighth transistor T8, which makes the eighth transistor T8 prone to leakage. By providing the eleventh transistor T11 and the twelfth transistor T12, the high level of the intermediate node T12 causes the twelfth transistor T12 to be turned on, so that the first and second electrodes of the eighth transistor T8 are at high level, reducing the voltage difference between the first and second electrodes of the eighth transistor T8 and thus achieving leakage prevention. Moreover, the low level of the input signal terminal IN also causes the eleventh transistor T11 to be turned off, thereby preventing the potential of the first electrode of the eighth transistor T8 from being affected by the second control signal terminal CKB.

The pull-down circuit 330 may have the same structure as the pull-down circuit 230 in the above embodiments, which will not be repeated here.

The cascaded output circuit includes a first cascaded sub-circuit 3401 and a second cascaded sub-circuit 3402. The first cascaded sub-circuit 3401 includes a third transistor T3 and a second capacitor C2. The description of the first cascaded sub-circuit with reference to FIG. 6 is also applicable to this embodiment. Unlike that shown in FIG. 6, the second cascaded sub-circuit 3402 includes not only the fourth transistor T4 and the third capacitor C2, but also the fifth transistor T5 and the sixth transistor T6. The second electrode of the fourth transistor T4 is coupled to the cascaded output terminal CR through the fifth transistor T5. As shown in FIG. 8, a first electrode of the fifth transistor T5 is coupled to the second electrode of the fourth transistor T4, a second electrode of the fifth transistor T5 is coupled to the cascaded output terminal CR, and a gate of the fifth transistor T5 is coupled to the pull-down node QB. A gate of the sixth transistor T6 is coupled to the cascaded output terminal CR, a first electrode of the sixth transistor T6 is coupled to the power signal terminal (first power signal terminal GVDD1), and a second electrode of the sixth transistor T6 is coupled to the pull-up node Q. The fifth transistor T5 and the sixth transistor T6 may also play a role in preventing leakage. Assuming that the fifth transistor T5 and the sixth transistor T6 are not provided, thee following situation will occur when the cascaded output terminal CR is at high level and the pull-down node QB is at low level: the fourth transistor T4 is in OFF state, but the first electrode of the fourth transistor T4 is at low level and the second electrode of the fourth transistor T4 is at high level, and there is a large potential difference between the first and second electrodes of the fourth transistor T4, which makes the fourth transistor T4 prone to leakage. By providing the fifth transistor T5 and the sixth transistor T6, the fifth transistor T5 is in OFF state due to the low level of the pull-down node QB and the first electrode of the fifth transistor T5 receives the high level of the cascaded output terminal CR, while the sixth transistor T6 is turned on by the high level of the cascaded output terminal CR so as to provide the high level of the first power signal terminal GVDD1 to the first electrode of the fifth transistor T5. In this way, the fifth transistor T5 is in OFF state, and the first and second electrodes of the fifth transistor T5 are at high level, thereby preventing leakage of the fifth transistor T5. At this point, even if the fourth transistor T4 leaks, the output signal of the cascaded output terminal CR may be prevented from being affected by the leakage of the fourth transistor T4, due to the provision of the fifth transistor T5.

In this embodiment, K=3, the signal output circuit includes a first output unit 350_1, a second output unit 350_2, and a third output unit 350_3. The descriptions of the first output unit 250_1, the second output unit 250_2, and the third output unit 250_3 in the above embodiments are also applicable to this embodiment, and will not be repeated here.

The reset circuit 360 is similar to the reset circuit 260 described above, except that the reset circuit 360 includes not only the sixteenth transistor T16 and the seventeenth transistor T17, but also the eighteenth transistor T18. The first electrode of the sixteenth transistor T16 is coupled to the reference signal terminal (first reference signal terminal VGL1) through the eighteenth transistor T18. As shown in FIG. 8, a gate of the eighteenth transistor T18 is coupled to the reset signal terminal TRS, a first electrode of the eighteenth transistor T18 is coupled to the reference signal terminal (first reference signal terminal VGL1), and a second electrode of the eighteenth transistor T18 is coupled to the first electrode of the sixteenth transistor. The eighteenth transistor T18 may also play a role in preventing leakage. For example, assuming that the eighteenth transistor T18 is not provided, the first and second electrodes of the sixteenth transistor T16 will be at low level and high level, respectively, when the reset signal terminal TRS is at low level and the pull-up node Q is at high level, which makes the sixteenth transistor T16 prone to leakage. By providing the eighteenth transistor T18, the eighteenth transistor T18 are turned off by the low level of the reset signal terminal TRS, and the first and second electrodes of the sixteenth transistor T16 are at high level, thereby preventing leakage of the sixteenth transistor T16.

The shift register unit described above with reference to FIG. 8 includes three output signal terminals, suitable for generating three driving signals, such as the driving signals required by the pixel circuit 10C described above, which will be described in detail below.

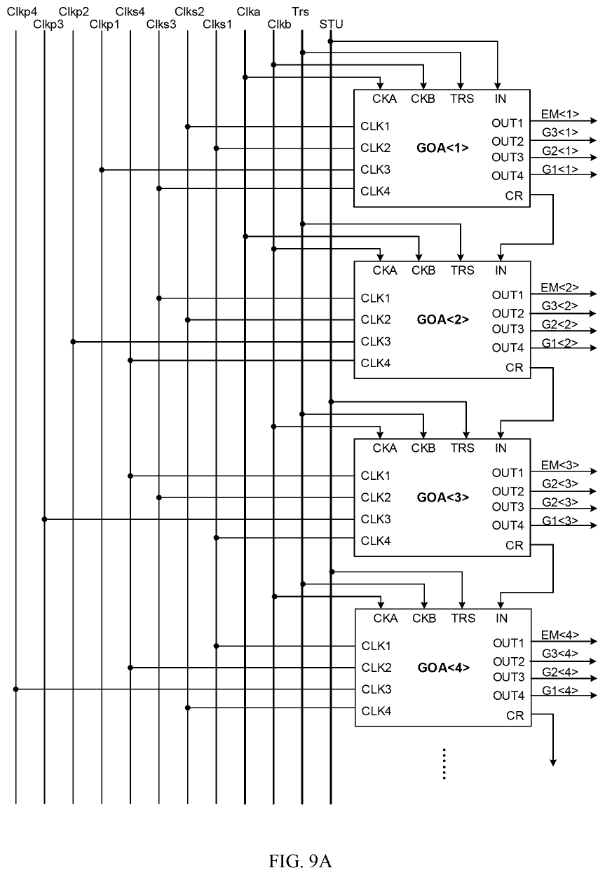

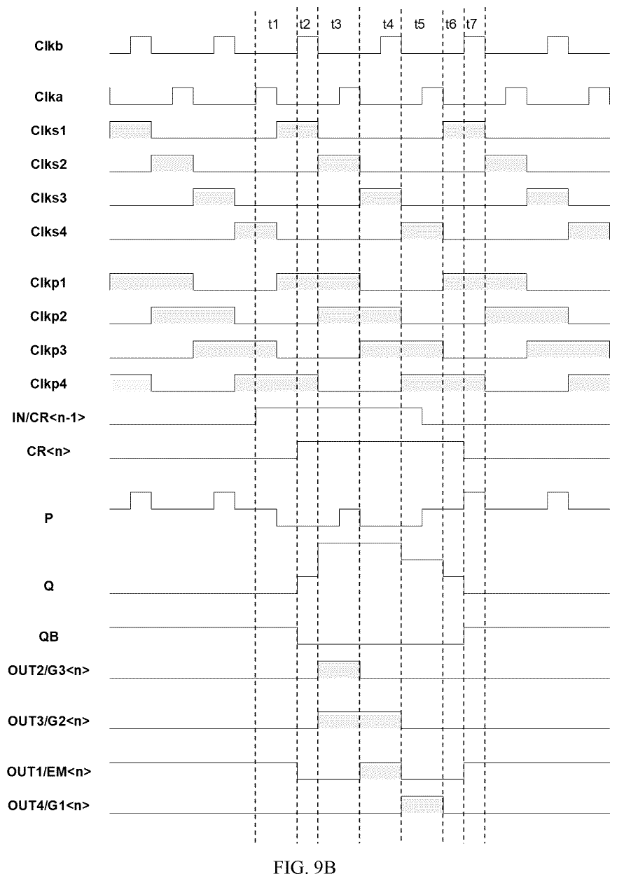

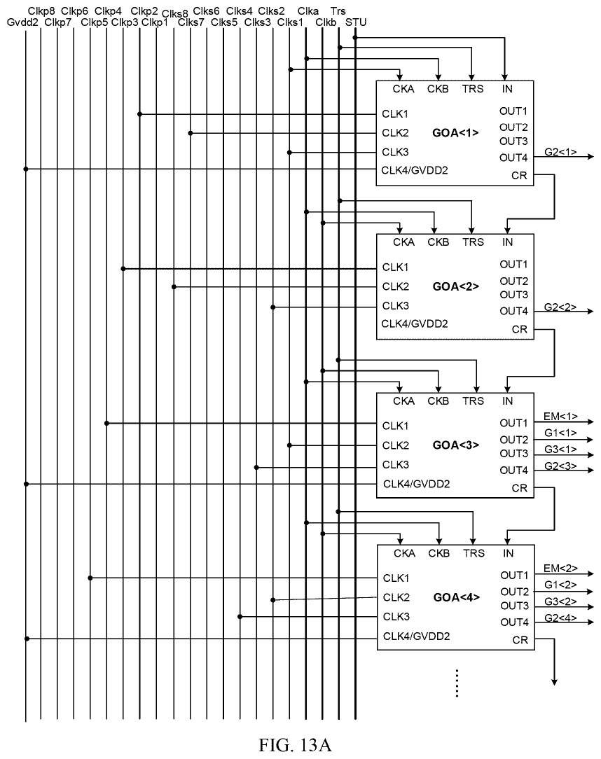

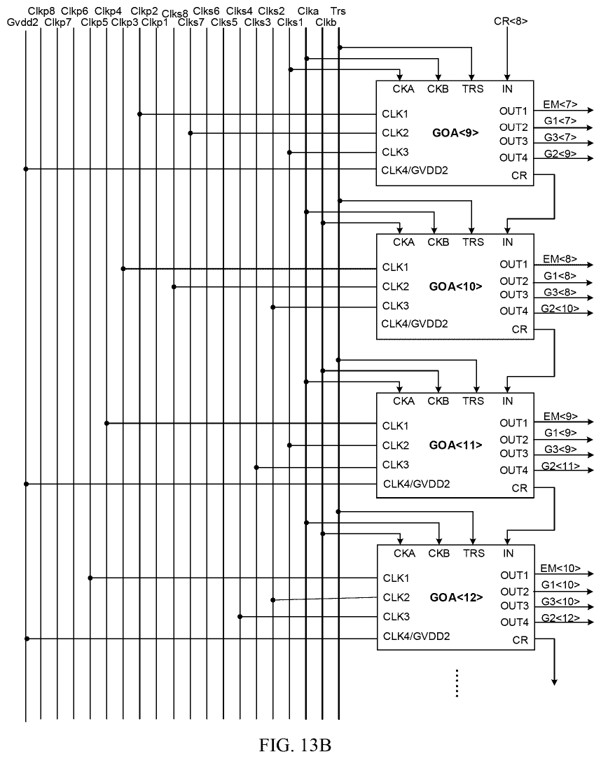

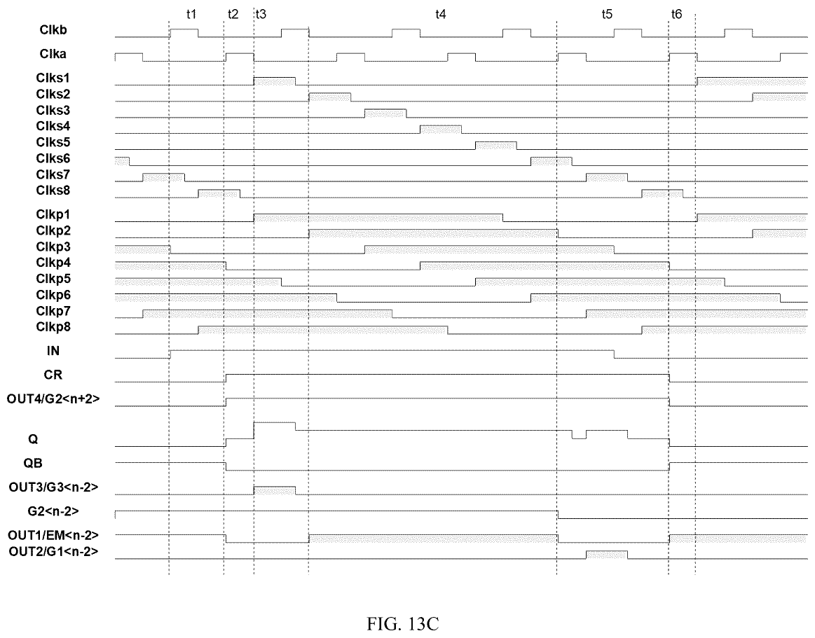

In some embodiments, the signal output circuit of the shift register unit may generate some or all of the K driving signals for driving a single sub-pixel. For example, assuming that driving a single sub-pixel requires a first gate driving signal G1, a second gate driving signal G2, a third gate driving signal G3, and a light-emitting control signal EM, a single shift register unit may be configured to generate all the driving signals required for the single sub-pixel, that is, the first gate driving signal G1, the second gate driving signal G2, the third gate driving signal G3, and the light-emitting control signal EM (which is described in detail below with reference to FIGS. 9A to 12B). It is also possible to generate the first gate driving signal G1, the third gate driving signal G3, and the light-emitting control signal EM required for the sub-pixel by a shift register unit, and generate the second gate driving signal G2 required for the sub-pixel by another shift register unit. In this way, the two shift register units cooperate with each other to provide all the required driving signals for the sub-pixel (which is described in detail below with reference to FIGS. 13A to 13C).

Embodiments of the present disclosure further provide a display driving circuit, including the shift register unit of any of the above embodiments, which is described in detail below with reference to FIGS. 9A to 13C.

FIG. 9A shows a schematic diagram of a display driving circuit according to an embodiment of the present disclosure.

As shown in FIG. 9A, the display driving circuit includes N cascaded shift register units GOA<1>, GOA<2>, . . . , GOA<N>. The shift register unit shown in FIG. 9A may be implemented as the shift register unit of any of the above embodiments, such as the shift register unit described above with reference to FIG. 6.

The cascaded output terminal CR of the n^{th} stage of shift register unit may be coupled to the input signal terminal IN of the (n+i)^{th} stage of shift register unit, where N, n, and i are positive integers and n<N. For example, as shown in FIG. 9A, i=1, the cascaded output terminal CR of the first stage of shift register unit GOA<1> is coupled to the input signal terminal IN of the second stage of shift register unit GOA<2>, the cascaded output terminal CR of the second stage of shift register unit GOA<2> is coupled to the input signal terminal IN of the third stage of shift register unit GOA<3>, and so on. The input signal terminal IN of the first stage of shift register unit GOA<1> may receive a start signal STU. Although i=1 is illustrated as an example in FIG. 9A, embodiments of the present disclosure are not limited to this and i may be set to other values as desired.

The display driving circuit may receive a plurality of clock signals, such as sequentially shifted M narrow clock signals and sequentially shifted M wide clock signals, where M is an integer multiple of K. As shown in FIG. 9A, M=4, the sequentially shifted M narrow clock signals are clock signals Clks1, Clks2, Clks3, and Clks4, and the sequentially shifted M wide clock signals are Clkp1, Clkp2, Clkp3, and Clkp4.

The K clock signal terminals of each shift register unit may receive K clock signals among a plurality of clock signals. For example, N shift register units may be divided into at least one set of shift register units, each set of shift register units includes M cascaded shift register units. M k1^{th} clock signal terminals of each set of shift register units are used to receive M narrow clock signals, respectively, and M k2^{th} clock signal terminals of each set of shift register units are used to receive M wide clock signals, respectively, where k1 and k2 are positive integers, 1≤k1<N, 1<k2≤N, and k 1≠k2. As shown in FIG. 9A, K=4, M=4, N shift register units are divided into a plurality of sets of shift register units, each set of shift register units including four shift register units. For example, the first set of shift register units includes first to fourth stages of shift register units GOA<1> to GOA<4>, the second set of shift register units includes fifth to eighth stages of shift register units GOA<5> to GOA<8>, and so on. The clock signal terminals CLK1, CLK2, and CLK4 of the shift register units in each set of shift register units receive narrow clock signals, and the clock signal terminals CLK3 of the shift register units in each set of shift register units receive wide clock signals.

As shown in FIG. 9A, taking the first set of shift register units as an example, the first clock signal terminal CLK1 of the first stage of shift register unit GOA<1> receives the second narrow clock signal Clks2, the first clock signal terminal CLK1 of the second stage of shift register unit GOA<2> receives the third narrow clock signal Clks3, the first clock signal terminal CLK1 of the third stage of shift register unit GOA<3> receives the fourth narrow clock signal Clks4, and the first clock signal terminal CLK1 of the fourth stage of shift register unit GOA<4> receives the first narrow clock signal Clks1. Similarly, the second clock signal terminals CLK2 of the shift register units GOA<1> to GOA<4> receive the first narrow clock signal Clks1, the second narrow clock signal Clks2, the third narrow clock signal Clks3, and the fourth narrow clock signal Clks4, respectively. The third clock signal terminals CLK3 of the shift register units GOA<1> to GOA<4> receive the first wide clock signal Clkp1, the second wide clock signal Clkp2, the third wide clock signal Clkp3, and the fourth wide clock signal Clkp1, respectively. The fourth clock signal terminals CLK4 of the shift register units GOA<1> to GOA<4> receive the third narrow clock signal Clks3, the fourth narrow clock signal Clks4, the first narrow clock signal Clks1, and the second narrow clock signal Clks2, respectively.

The clock signal terminals of the first to fourth stages of shift register units GOA<5> to GOA<8> (i.e. the fifth to eighth stages of shift register units in the entire display driving circuit) in the second set of shift register units are coupled in the same methods. Specifically, the first clock signal terminals CLK 1 of the shift register units GOA<5> to GOA<8> receive clock signals Clks2, Clks3, Clks4, and Clks1, respectively. The second clock signal terminals CLK2 of the shift register units GOA<5> to GOA<8> receive clock signals Clks1, Clks2, Clks3, and Clks4, respectively. The third clock signal terminals CLK3 of the shift register units GOA<5> to GOA<8> receive clock signals Cklp1, Clkp2, CLkp3, and Clkp4, respectively. The fourth clock signal terminals CLK4 of the shift register units GOA<5> to GOA<8> receive clock signals Clks3, Clks4, Clks1, and Clks2, respectively. The clock signal terminals of the third set of shift register units GOA<9> to GOA<12> are also coupled in the same methods, and so on.

The first control signal terminal CKA and the second control signal terminal CKB of each shift register unit receive the first control signal Cka and the second control signal Ckb. As shown in FIG. 9A, the first control signal terminals CKA of the odd-numbered stages of shift register units GOA<1>, GOA<3>, GOA<5> . . . receive the first control signal Cka, and the second control signal terminals CKB of the odd-numbered stages of shift register units GOA<1>, GOA<3>, GOA<5> . . . receive the second control signal Ckb. The first control signal terminals CKA of the even-numbered stages of shift register units GOA<2>, GOA<4>, GOA<6> . . . receive the second control signal Ckb, and the second control signal terminals CKB of the even-numbered stages of shift register units GOA<2>, GOA<4>, GOA<6> . . . receive the second control signal Cka. However, embodiments of the present disclosure are not limited to this, and the coupling method of the odd-numbered stages of shift register units and the coupling method of the even-numbered stages of the shift register units may be interchanged.

The reset signal terminal TRS of each shift register unit GOA<1>, GOA<2>, . . . GOA<N> receives the reset signal Trs. As shown in FIG. 6, the power signal terminal and reference signal terminal of each shift register may receive the corresponding power signal and the corresponding reference signal. For example, the first power signal terminal GVDD1 may receive the first power signal, the first reference signal terminal VGL1 may receive the first reference signal, the second power signal terminal GVDD2 may receive the second power signal, and the second reference signal terminal VGL2 may receive the second reference signal, which will not be repeated here.

The display driving circuit may be used to drive a plurality of rows of sub-pixels. The K output signal terminals of each shift register unit provide display driving signals to a corresponding row of sub-pixels among the plurality of rows of sub-pixels. According to embodiments of the present disclosure, the display driving signals include the gate driving signal and the light-emitting control signal for driving the row of sub-pixels. For example, as shown in FIG. 9A, the output signal terminals OUT1, OUT2, OUT3, and OUT4 of each shift register unit may output the first gate driving signal G1, the second gate driving signal G2, the third gate driving signal G3, and the light-emitting control signal EM required for the pixel circuit described above with reference to FIGS. 1 and 2. The following provides a detailed description with reference to the signal timing shown in FIG. 9B.

FIG. 9B shows a signal timing diagram of the display driving circuit shown in FIG. 9A.

As shown in FIG. 9B, the display driving circuit receives four narrow clock signals Clks1 to Clks4 that are sequentially shifted and four wide clock signals Clkp1 to Clkp4 that are sequentially shifted. The clock signals Clks1, Clks2Clks2, Clks3, Clks4 are sequentially shifted by H in the order of Clks1, Clks2, Clks3, Clks4; and the clock signals Clkp1, Clkp2, Clkp3, and Clkp4 are sequentially shifted by H in the order of Clkp1, Clkp2, Clkp3, and Clkp4, where H represents the scanning time period per unit, which is the time period required to scan one row of sub-pixels, that is, the time interval from generating the gate driving signal for a row of sub-pixels to generating the gate driving signal for the next row of sub-pixels. The duty cycle of the narrow clock signal is less than the duty cycle of the wide clock signal. For example, the duty cycle of the wide clock signal may be twice that of the narrow clock signal. As shown in FIG. 9B, the clock cycle of each of the narrow clock signals Clks1 to Clks14 and the clock cycle of each of the wide clock signals Clkp1 to Clkp14 are both 4H, and the valid level duration of each of the narrow clock signals Clks1 to Clks4 is H, the valid level duration of each of the wide clock signals Clkp1 to Clkp4 is 2H.

The first control signal Clka and the second control signal Clkb may have the same cycle and be relatively shifted, such that when one of the first control signal Clka and the second control signal Clkb is at high level, the other one of the first control signal Clka and the second control signal Clkb is at low level. For example, as shown in FIG. 9B, the valid level duration of each of the first control signal Clka and the second control signal Clkb may be half H, and the shift between the first control signal Clka and the second control signal Clkb may be H, so that a time period in which the first control signal Clka is at high level is different from a time period in which the second control signal Clkb is at high level.

In FIG. 9B, signal timing is illustrated by taking the n^{th} stage of shift register unit GOA<n> shown in FIG. 9A which has the circuit structure as described above with reference to FIG. 6, as an example. Combining reference to FIG. 6 and FIG. 9A, in a case that n=2, the clock signal terminals CLK1 to CLK4 of the shift register unit GOA<2> receive clock signals Clks3, Clks2, Clkp2, and Clks4, respectively. The input signal terminal IN of the shift register unit GOA<2> receives the signal CR<1> from the cascaded output terminal of the previous stage of shift register unit GOA<1> as the input signal. The first control signal terminal CKA of the shift register unit GOA<2> receives the second control signal Ckb, and the second control signal terminal CKB of the shift register unit GOA<2> receives the first control signal Cka.

In a period t1, the signal CR<n−1> (i.e. CR<1>) output from the cascaded output terminal of the previous stage of shift register unit is at high level, that is, the input signal terminal IN of the shift register unit GOA<2> shown in FIG. 9A is at high level. Referring to FIG. 6, the high level of the input signal terminal IN causes the transistor T8 to be turned on, thereby providing the signal of the second control signal terminal CKB to the intermediate node P. From FIG. 9A, it may be seen that the potential of the intermediate node P follows the potential of the first control signal Cka received at the second control signal terminal CKB. In this period, due to the second clock signal Ckb being at low level, the first control signal terminal CKA of the shift register unit GOA<2> shown in FIG. 9A is at low level, referring to FIG. 6, the transistor T14 is in OFF state, the pull-up node Q is kept at low level, so that the transistor T3 as well as the transistors T1_1, T1_2, T1_3, and T1_4 are in OFF state, and the cascaded output terminal CR and output signal terminals OUT1 to OUT4 are kept at their previous potentials.

In a period t2, the second control signal Ckb is at high level, that is, the first control signal terminal CKA of the shift register unit GOA<2> shown in FIG. 9A is at high level. Referring to FIG. 6, the high level of the first control signal terminal CKA causes the transistors T14 and T15 to be turned on, and the high level of the input signal terminal IN is provided to the pull-up node Q and the node QH. The high level of the node QH causes the transistor T13 to be turned on, so that the pull-down node QB is pulled down to the low level of the first reference signal terminal VGL1. The high level of the pull-up node Q causes the transistor T3 to be turned on, so that the high level of the first power signal terminal GVDD1 is provided to the cascaded output terminal CR (CR<n> as shown in FIG. 9A). The high level of the pull-up node Q also causes the transistors T1_1, T1_2, T1_3, and T1_4 to be turned on. As the clock signals Clks3, Clks2, Clkp2, and Clks4 respectively received by the clock signal terminals CLK1 to CLK4 of the shift register unit GOA<2> are at low level, the output signal terminals OUT1 to OUT4 are at low level.

In a period t3, the clock signals Clks2 and Clkp2 received by the clock signal terminals CLK2 and CLK3 of the shift register unit GOA<2> are at high level, and the clock signals Clks3 and Clks4 received by the clock signal terminals CLK1 and CLK4 are at low level. Referring to FIG. 6, the turned-on transistors T1_2 and T1_3 provide the high-level clock signals Clks2 and Clkp2 to the output signal terminals OUT2 and OUT3, and the turned-on transistors T1_1 and T1_4 provide the low-level clock signals Clks3 and Clks4 to the output signal terminals OUT1 and OUT4. Due to the high level of the output signal terminals OUT2 and OUT3, the bootstrap effect of the capacitors C1_2 and C1_3 further increases the potential of the pull-up node Q.

In a period t4, the clock signals Clks3 and Clkp2 are at high level, and the clock signals Clks2 and Clks4 are at low level. The turned-on transistors T1_3 and T1_1 provide the high-level clock signals Clks3 and Clkp2 to the output signal terminals OUT3 and OUT1, and the turned-on transistors T1_2 and T1_4 provide the low-level clock signals Clks2 and Clks4 to the output signal terminals OUT1 and OUT4.

In a period t5, the clock signal Clks4 is at high level, and the clock signals Clks2, Clks3, and Clkp2 are at low level. The turned-on transistor T1_4 provides the high-level clock signal Clks4 to the output signal terminal OUT4, and the turned-on transistors T1_2, T1_3, and T1_4 provide the low-level clock signals Clks2, Clks3, and Clkp2 to the output signal terminals OUT1, OUT3, and OUT4, respectively.

In a period t6, the clock signals Clks3, Clks2, Clkp2, and Clks4 are at low level, so that the output signal terminals OUT1 to OUT4 are at low level. The bootstrap effect of the capacitors C1_1 to C1_4 causes the voltage of the pull-up node Q to drop. In this process, the signal CR<n−1> (i.e. CR<1>) output from the cascaded output terminal of the previous stage of shift register unit is at low level, that is, the input signal terminal IN of the shift register unit GOA<2> shown in FIG. 9A is at low level. The first control signal Cka and the second control signal Ckb are both at low level, that is, the first control signal terminal CKA and the second control signal terminal CKB of the shift register unit GOA<2> are both at low level. Referring to FIG. 6, the low level of the input signal terminal IN and the low level of the second control signal terminal CKB respectively cause the transistor T8 and the transistor T7 to be turned off, and the intermediate node P is kept at the previous high level.

In a period t7, the second control signal Ckb is switched to high level, and the first control signal terminal CKA of the shift register unit GOA<2> is at high level, referring to FIG. 6, the transistors T14 and T15 are turned on, so that the low level of the input signal terminal IN is provided to the pull-up node Q and the node QH. The high level of the first control signal terminal CKA also causes the transistor T10 to be turned on. The turned-on transistors T9 and T10 provide the high level of the first control signal terminal CKA to the pull-down node QB. The high level of the pull-down node QB causes the transistor T4 as well as the transistors T2_1, T2_2, T2_3, and T2_4, to be turned on, resulting in low level output at the cascaded output terminal CR as well as output signal terminals OUT2, OUT3, and OUT4, and high level output at the output signal terminal OUT1.

At this point, the shift register unit GOA<2> has completed the output of the display driving signal. As shown in FIG. 9B, the signals output from the output signal terminals OUT1 to OUT4 of the shift register unit GOA<2> may be used as the light-emitting control signal EM, the third gate driving signal G3, the second gate driving signal G2, and the first gate driving signal G1 of the pixel driving circuit described above with reference to FIGS. 1 and 2, respectively. From FIG. 9B, it may be seen that signals output from at least two of the K output signal terminals have different duty cycles. For example, the duty cycle of the signal output from the output signal terminal OUT3 is greater than the duty cycle of the signal output from the output signal terminal OUT2 and the duty cycle of the signal output from the output signal terminal OUT4. The so-called duty cycle here refers to the ratio of the valid level duration to the length of period in one cycle (such as one frame).

Other stages of shift register units operate in a similar method. The sub-pixels are arranged in an array, and the sub-pixels located in the same row are driven by the same set of display driving signals. Due to the fact that each stage of shift register unit may generate multiple display driving signals for driving a single sub-pixel, each stage of shift register unit may provide the corresponding row of pixels with the required multiple display driving signals. For example, in conjunction with FIG. 9A, the first stage of shift register unit GOA<1> generates the light-emitting control signal EM<1>, the first gate driving signal G1<1>, the second gate driving signal G2<1>, and the third gate driving signal G3<1> for driving the first row of sub-pixels; the second stage of shift register unit GOA<2> generates the light-emitting control signal EM<2>, the first gate driving signal G1<2>, the second gate driving signal G2<2>, and the third gate driving signal G3<2> for driving the second row of sub-pixels, and so on.

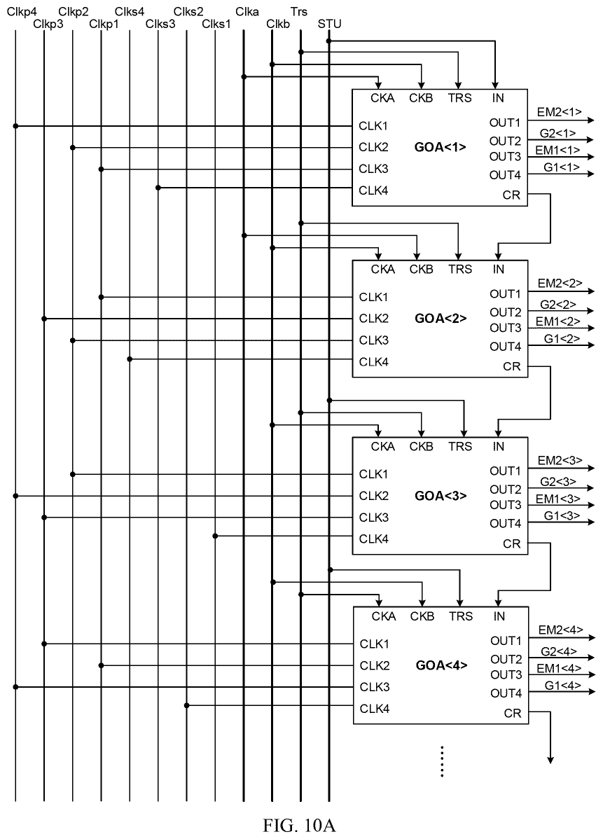

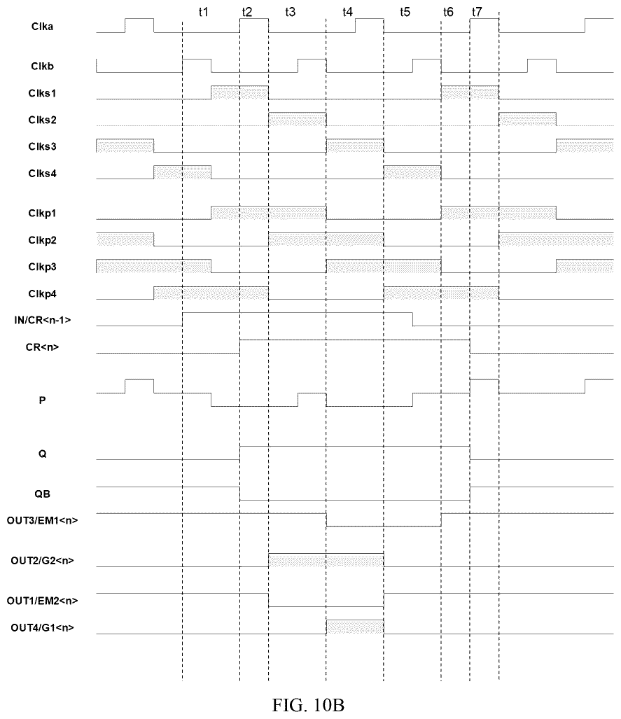

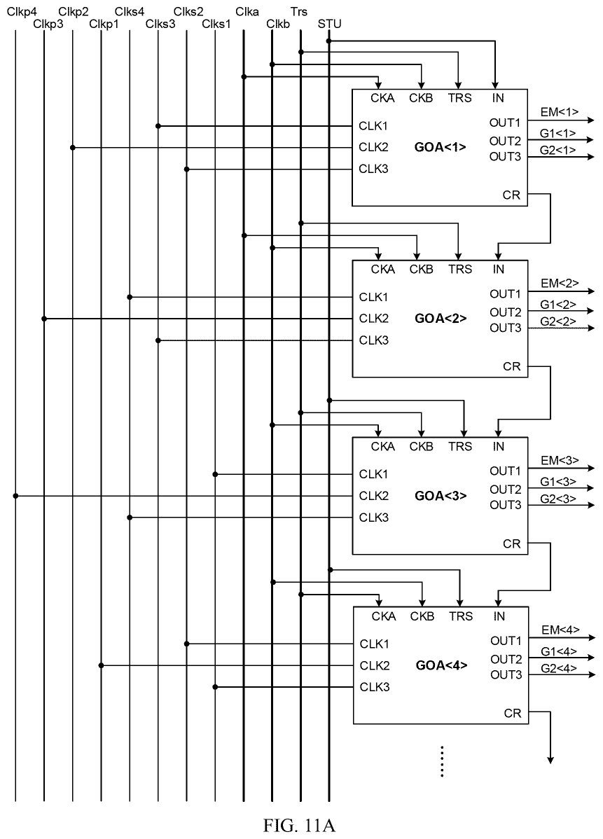

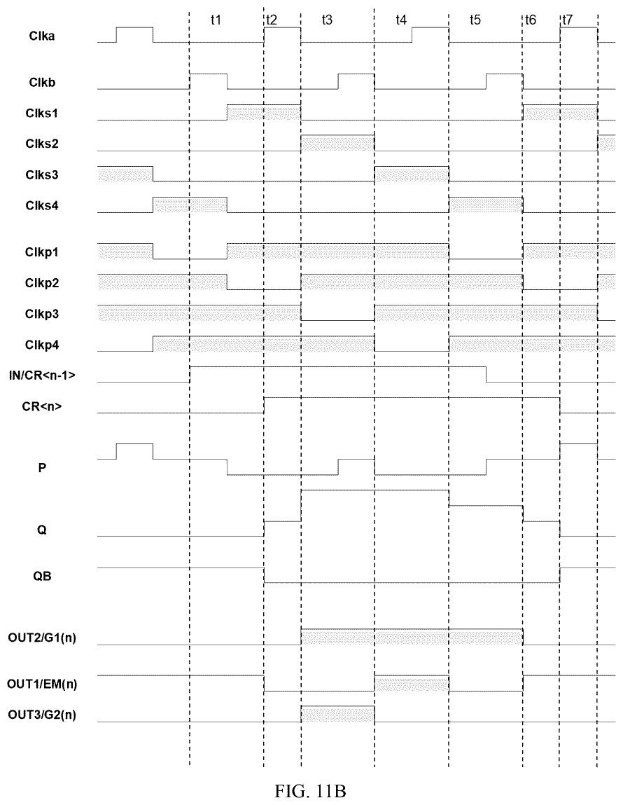

FIG. 10A shows a schematic diagram of a display driving circuit according to another embodiment of the present disclosure. The shift register unit in the display driving circuit may be implemented as the shift register unit of any of the above embodiments, such as the shift register unit described above with reference to FIG. 6. The display driving circuit shown in FIG. 10A is similar to that shown in FIG. 9A, with a difference at least in the coupling of the clock signal terminals. Detailed description will be made mainly on the differences in the following.

In the example shown in FIG. 10A, K=4, i=1, M=4, N shift register units are also divided into sets of shift register units, and each set of shift register units includes four shift register units. Each of the shift register units GOA1<1>, GOA1<2>, . . . , GOA1<N> includes four output units, which receive four clock signals at the four clock signal terminals CLK1 to CLK4 respectively and generate four output signals at the four output signal terminals OUT1 to OUT4 respectively. As shown in FIG. 10A, taking the first set of shift register units as an example, the first clock signal terminal CLK1 of the first stage of shift register unit GOA1<1> in the first set of shift register units receives the fourth wide clock signal Clkp4, the first clock signal terminal CLK1 of the second stage of shift register unit GOA1<2> in the first set of shift register units receives the first wide clock signal Clkp1, the first clock signal terminal CLK 1 of the third stage of shift register unit GOA1<3> in the first set of shift register units receives the second wide clock signal Clkp2, and the first clock signal terminal CLK1 of the fourth stage of shift register unit GOA1<4> in the first set of shift register units receives the third wide clock signal Clkp3. Similarly, the second clock signal terminals CLK2 of the shift register units GOA1<1> to GOA1<4> respectively receive the second wide clock signal Clkp2, the third wide clock signal Clkp3, the fourth wide clock signal Clkp4, and the first wide clock signal Clkp1. The third clock signal terminals CLK3 of the shift register units GOA1<1> to GOA1<4> respectively receive the first wide clock signal Clkp1, the second wide clock signal Clkp2, the third wide clock signal Clkp3, and the fourth wide clock signal Clkp4. The fourth clock signal terminals CLK4 of the shift register units GOA1<1> to GOA1<4> respectively receive the third narrow clock signal Clks3, the fourth narrow clock signal Clks4, the first narrow clock signal Clks1, and the second narrow clock signal Clks2.

The clock signal terminals of other sets of shift register units are coupled in the same method and will not be repeated here. The first control signal terminal CKA and the second control signal terminal CKB of each shift register unit are coupled in the same manner as that described above with reference to FIG. 9A, and will not be repeated here.

The output signals of the output signal terminals OUT1, OUT2, OUT3, and OUT4 of each shift register unit may be used as the first gate driving signal G1, the second gate driving signal G2, the first light-emitting control signal EM1, and the second light-emitting control signal EM2 required for the pixel circuit 1B described above. The following provides a detailed description with reference to the signal timing shown in FIG. 10B.

FIG. 10B shows a signal timing diagram of the display driving circuit shown in FIG. 10A. As shown in FIG. 10B, the operating mode of each shift register unit in the display driving circuit is similar to the operating mode described above with reference to FIG. 9B, except that the shift register unit is controlled by different clock signals to generate different display driving signals. Detailed description will be made mainly on the differences in the following.

Combining reference to FIG. 6, FIG. 10A, and FIG. 10B, taking n=1 as an example, the clock signal terminals CLK1 to CLK4 of the shift register unit GOA<1> receive clock signals Clkp4, Clkp2, Clkp1, and Clks3, respectively.

In a period t1, the input signal terminal IN of the shift register unit GOA<1> is at high level, so that the transistor T8 of the shift register unit is turned on, thereby providing the signal of the second control signal terminal CKB to the intermediate node P. From FIG. 9A, it may be seen that the potential of the intermediate node P follows the potential of the first control signal Ckb received at the second control signal terminal CKB. In this period, due to the first clock signal Cka being at low level, the first control signal terminal CKA of the shift register unit GOA<1> shown in FIG. 10A is at low level. Accordingly, referring to FIG. 6, the transistor T14 is in OFF state. The pull-up node Q is kept at low level, so that the transistor T3 as well as the transistors T1_1, T1_2, T1_3, and T1_4 are in OFF state, and the cascaded output terminal CR and output signal terminals OUT1 to OUT4 are kept at their previous potentials.

In a period t2, the first control signal Cka is at high level, that is, the first control signal terminal CKA of the shift register unit GOA<1> shown in FIG. 10A is at high level. Referring to FIG. 6, the high level of the first control signal terminal CKA causes the transistors T14 and T15 to be turned on, so that the high level of the input signal terminal IN is provided to the pull-up node Q and the node QH. The high level of the node QH causes the transistor T13 to be turned on, so that the pull-down node QB is pulled down to the low level of the first reference signal terminal VGL1. The high level of the pull-up node Q causes the transistor T3 to be turned on, thereby providing the high level of the first power signal terminal GVDD1 to the cascaded output terminal CR (CR<n> as shown in FIG. 10B). The high level of the pull-up node Q also causes the transistors T1_1, T1_2, T1_3, and T1_4 to be turned on. As the clock signals Clkp4 and Clkp1 received by the clock signal terminals CLK1 and CLK3 of the shift register unit GOA<1> are at high level and the clock signals Clkp2 and Clks3 received by the clock signal terminals CLK2 and CLK4 are at low level, the output signal terminals OUT1 and OUT3 are at high level and the output signal terminals OUT2 and OUT4 are at low level.

In periods t3 to t5, the shift register unit GOA<1> is operated in a similar manner as in the periods t3 to t5 described with reference to FIG. 9B, such that the first output unit 250_1 generates an output signal at the first output signal terminal OUT1 based on the clock signal Clkp4, the second output unit 250_2 generates an output signal at the output signal terminal OUT2 based on the clock signal Clkp2, the third output unit 250_3 generates an output signal at the output signal terminal OUT3 based on the clock signal Clkp1, and the fourth output unit 250_4 generates an output signal at the output signal terminal OUT4 based on the clock signal Clks3, as shown in FIG. 10B, which will not be repeated here.

In a period t6, the clock signals Clkp4 and Clkp1 are at high level, and the clock signals Clkp2 and Clks3 are at low level, so that the output signal terminals OUT1 and OUT3 are at high level and the output signal terminals OUT2 and OUT4 are at low level. The start signal received by the input signal terminal IN of the shift register unit GOA<1>, the first control signal Clka received by the first control signal terminal CKA of the shift register unit GOA<2>, and the second control signal Clkb received by the second control signal terminal CKB of the shift register unit GOA<2> are at low level. Referring to FIG. 6, the low level of the input signal terminal IN and the low level of the second control signal terminal CKB respectively cause the transistors T8 and T7 to be turned off, and the intermediate node P is kept at the previous high level.

In a period t7, the first control signal Clka received by the first control signal terminal CKA of the shift register unit GOA<1> is switched to high level. Accordingly, referring to FIG. 6, the transistors T14 and T15 are turned on, so that the low level of the input signal terminal IN is provided to the pull-up node Q and the node QH. The high level of the first control signal terminal CKA also causes the transistor T10 to be turned on. The turned-on transistors T9 and T10 provide the high level of the first control signal terminal CKA to the pull-down node QB. The high level of the pull-down node QB causes the transistor T4, as well as the transistors T2_1, T2_2, T2_3, and T2_4, to be turned on, resulting in low level output at the cascaded output terminal CR as well as output signal terminals OUT2 and OUT4, and high level output at the output signal terminals OUT1 and OUT3.

At this point, the shift register unit GOA<1> has completed the output of the display driving signals. As shown in FIG. 10B, the signals output from the output signal terminals OUT1 to OUT4 of the shift register unit GOA<1> may be used as the second light-emitting control signal EM2, the second gate driving signal G2, the first light-emitting control signal EM1, and the first gate driving signal G1 of the pixel driving circuit 10B, respectively.

Other stages of shift register units operate in a similar manner, such that each stage of shift register unit provides multiple display driving signals required by a corresponding row of pixels. With reference to FIG. 10A, the first stage of shift register unit GOA<1> generates the first light-emitting control signal EM1<1>, the second light-emitting control signal EM2<1>, the first gate driving signal G1<1>, and the second gate driving signal G2<1> for driving the first row of sub-pixels; the second stage of shift register unit GOA<2> generates the first light-emitting control signal EM1<2>, the second light-emitting control signal EM2<2>, the first gate driving signal G1<2>, and the second gate driving signal G2<2> for driving the second row of sub-pixels, and so on.

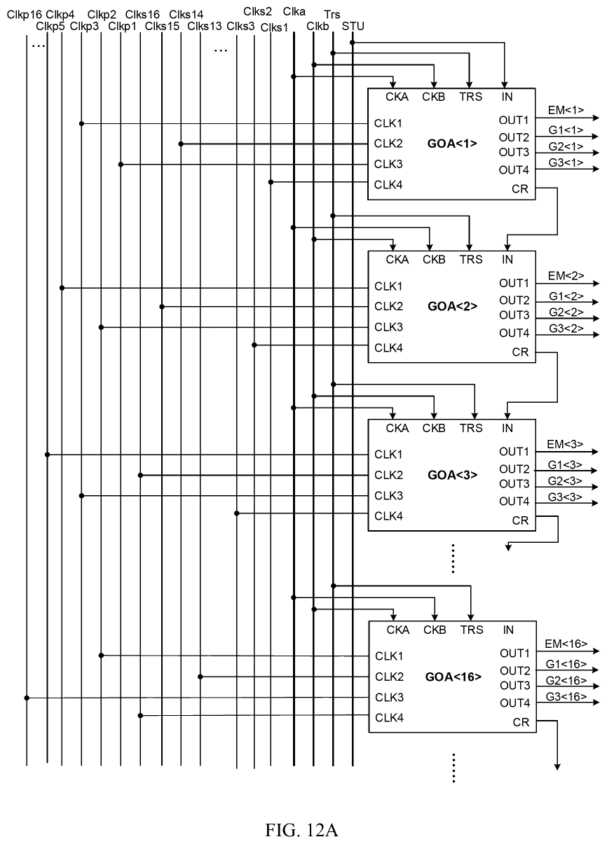

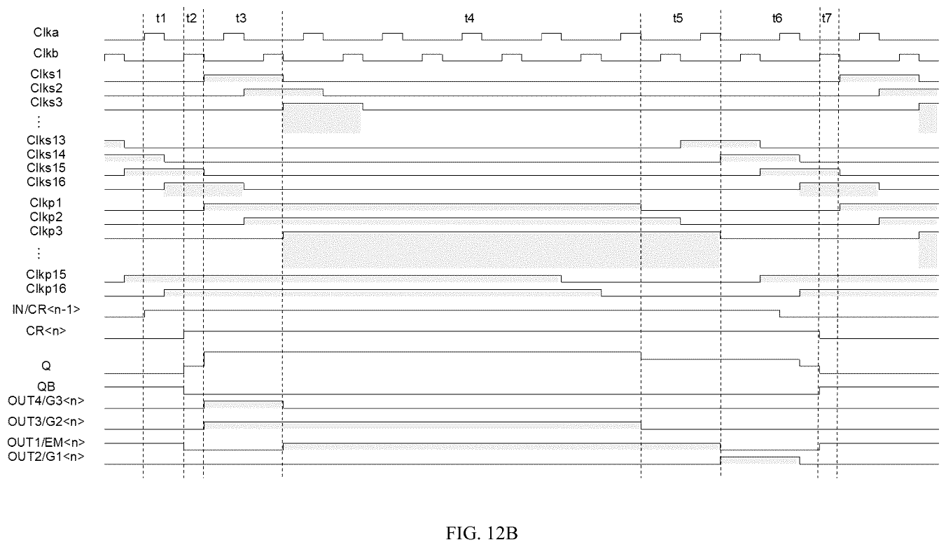

FIG. 11A shows a schematic diagram of a display driving circuit according to another embodiment of the present disclosure. The shift register unit in the display driving circuit may be implemented as the shift register unit of any of the above embodiments, such as the shift register unit described above with reference to FIG. 8. The display driving circuit shown in FIG. 11A is similar to that shown in FIG. 9A, with a difference at least in the coupling of the clock signal terminals. Detailed description will be made mainly on the differences in the following.

In the example shown in FIG. 11A, K=3, i=1, and M=4. N shift register units are also divided in sets of shift register units, and each set of shift register units includes four shift register units. Each of the shift register units GOA1<1>, GOA1<2>, . . . , GOA1<N> includes three output units. The three output units receive the corresponding three clock signals at the three clock signal terminals CLK1 to CLK3 and generate three output signals at the three output signal terminals OUT1 to OUT3. As shown in FIG. 11A, taking the first set of shift register units as an example, the first clock signal terminal CLK1 of the first stage of shift register unit GOA1<1> in the first set of shift register units receives the third narrow clock signal Clks3, the first clock signal terminal CLK1 of the second stage of shift register unit GOA1<2> in the first set of shift register units receives the fourth narrow clock signal Clks4, the first clock signal terminal CLK1 of the third stage of shift register unit GOA1<3> in the first set of shift register units receives the first narrow clock signal Clks1, and the first clock signal terminal CLK1 of the fourth stage of shift register unit GOA1<4> in the first set of shift register units receives the second narrow clock signal Clks2. Similarly, the second clock signal terminals CLK2 of the shift register units GOA1<1> to GOA1<4> respectively receive the second wide clock signal Clkp2, the third wide clock signal Clkp3, the fourth wide clock signal Clkp4, and the first wide clock signal Clkp1. The third clock signal terminals CLK3 of the shift register units GOA1<1> to GOA1<4> respectively receive the second narrow clock signal Clks2, the third narrow clock signal Clks3, the fourth narrow clock signal Clks4, and the first narrow clock signal Clks1.

The clock signal terminals of other sets of shift register units are coupled in the same manner and will not be repeated here. The other signal terminals of each shift register unit, such as the control signal terminal, power signal terminal, and reference signal terminal, may be coupled in a manner described above with reference to FIG. 9A, and will not be repeated here.

The output signals of the output signal terminals OUT1, OUT2, and OUT3 of the shift register unit may be used as the light-emitting control signal EM, the first gate driving signal G1, and the second gate driving signal G2 required for the pixel circuit 10C, respectively. The following provides a detailed description with reference to the signal timing shown in FIG. 11B.

FIG. 11B shows a signal timing diagram of the display driving circuit shown in FIG. 11A. As shown in FIG. 11B, each shift register unit in the display driving circuit is operated in the similar as that described above with reference to FIG. 9B, except that the shift register unit is controlled by different clock signals to generate different display driving signals. Detailed description will be made mainly on the differences in the following.

Combining reference to FIG. 8, FIG. 11A, and FIG. 11B, taking n=1 as an example, the clock signal terminals CLK1 to CLK3 of the shift register unit GOA<1> receive clock signals Clks3, Clkp2, and Clks2, respectively.

In a period t1, the input signal terminal IN of the shift register unit GOA<1> is at high level, so that the transistor T8 of the shift register unit is turned on, thereby providing the signal of the second control signal terminal CKB to the intermediate node P. From FIG. 9A, it may be seen that the potential of the intermediate node P follows the potential of the first control signal Ckb received at the second control signal terminal CKB. In this period, due to the first clock signal Cka being at low level, the first control signal terminal CKA of the shift register unit GOA<1> is at low level. Accordingly, referring to FIG. 8, the transistor T14 is in OFF state. The pull-up node Q is kept at low level, so that the transistor T3, as well as the transistors T1_1, T1_2, T1_3, and T1_4, are in OFF state. The cascaded output terminal CR and the output signal terminals OUT1 to OUT4 are kept at their previous potentials.

In a period t2, the first control signal Cka received by the first control signal terminal CKA of the shift register unit GOA<1> is at high level. Referring to FIG. 8, the high level of the first control signal terminal CKA causes the transistors T14 and T15 to be turned on, so that the high level of the input signal terminal IN is provided to the pull-up node Q and the node QH. The high level of the node QH causes the transistor T13 to be turned on, so that the pull-down node QB is pulled down to the low level of the first reference signal terminal VGL1. The high level of the pull-up node Q causes the transistor T3 to be turned on, thereby providing the high level of the first power signal terminal GVDD1 to the cascaded output terminal CR (CR<n>as shown in FIG. 10B). The high level of the pull-up node Q also causes the transistors T1_1, T1_2, T1_3, and T1_4 to be turned on. As the clock signals Clks3, Clkp2, and Clks2 received by the clock signal terminals CLK1 to CLK3 of the shift register unit GOA<1> are at low level, the output signal terminals OUT1 to OUT3 are at low level.

In periods t3 to t5, the shift register unit GOA<1> is operated in a similar manner as in the periods t3 to t5 described above with reference to FIG. 9B, such that the first output unit 350_1 generates an output signal at the first output signal terminal OUT1 based on the clock signal Clks3, the second output unit 350_2 generates an output signal at the output signal terminal OUT2 based on the clock signal Clkp2, and the third output unit 350_3 generates an output signal at the output signal terminal OUT3 based on the clock signal Clks2, as shown in FIG. 11B, which will not be repeated here.

In a period t6, the clock signals Clks3, Clkp2, and Clks2 are at low level, so that the output signal terminals OUT1 to OUT3 are at low level. The start signal received by the input signal terminal IN of the shift register unit GOA<1>, the first control signal Clka received by the first control signal terminal CKA of the shift register unit GOA<2>, and the second control signal Clkb received by the second control signal terminal CKB of the shift register unit GOA<2> are at low level. Referring to FIG. 8, the low level of the input signal terminal IN and the low level of the second control signal terminal CKB respectively cause the transistors T8 and T7 to be turned off, and the intermediate node P is kept at the previous high level.

In a period t7, the first control signal Clka received by the first control signal terminal CKA of the shift register unit GOA<1> is switched to high level. Accordingly, referring to FIG. 8, the transistors T14 and T15 are turned on, so that the low level of the input signal terminal IN is provided to the pull-up node Q and the node QH. The high level of the first control signal terminal CKA also causes the transistor T10 to be turned on. The turned-on transistors T9 and T10 provide the high level of the first control signal terminal CKA to the pull-down node QB. The high level of the pull-down node QB causes the transistor T4, as well as the transistors T2_1, T2_2, T2_3, and T2_4, to be turned on, resulting in low level output at the cascaded output terminal CR as well as output signal terminals OUT2 and OUT3, and high level output at the output signal terminal OUT1.

At this point, the shift register unit GOA<1> has completed the output of the display driving signal. As shown in FIG. 11B, the signals output from the output signal terminals OUT1 to OUT3 of the shift register GOA<1> may be used as the light-emitting control signal EM, the first gate driving signal G1, and the second gate driving signal G2 of the pixel circuit 10C, respectively.

Other stages of shift register units operate in a similar method, so that each stage of shift register unit may provide multiple display driving signals required by the corresponding row of pixels. With reference to FIG. 11A, the first stage of shift register unit GOA<1> generates the light-emitting control signal EM<1>, the first gate driving signal G1<1>, and the second gate driving signal G2<1> for driving the first row of sub-pixels; the second stage of shift register unit GOA<2> generates the light-emitting control signal EM<2>, the first gate driving signal G1<2>, and the second gate driving signal G2<2> for driving the second row of sub-pixels, and so on.

FIG. 12A shows a schematic diagram of a display driving circuit according to another embodiment of the present disclosure. The shift register unit in the display driving circuit may be implemented as the shift register unit of any of the above embodiments, such as the shift register unit described above with reference to FIG. 6. The display driving circuit shown in FIG. 12A is similar to that shown in FIG. 9A, with a difference at least in the coupling of the clock signal terminals, as well as the number of the clock signals and the duty cycles of the clock signals. Detailed description will be made mainly on the differences in the following.

In the example of FIG. 12A, K=4, i=1, M=16, the display driving circuit receives sixteen sequentially shifted narrow clock signals Clks1 to Clks16 and sixteen sequentially shifted wide clock signals Clkp1 to Clkp16. N shift register units are divided into sets of shift register units, and each set of shift register units includes sixteen shift register units, for example, the first set of shift register units includes shift register units GOA1<1> to GOA1<16>, the second set of shift register units includes shift register units GOA1<17> to GOA1<32>, and so on. Each of the shift register units GOA1<1>, GOA1<2>, . . . , GOA1<N> includes four output units, which respectively receive the corresponding four clock signals at the four clock signal terminals CLK1 to CLK4 and generate corresponding four output signals at the four output signal terminals OUT1 to OUT4.

As shown in FIG. 12A, in the first set of shift register units, the first clock signal terminals CLK1 of the first to sixteenth stages of shift register units GOA1<1> to GOA1<16> respectively receive sixteen wide clock signals sequentially shifted from the third wide clock signal Clkp3, i.e. Clkp3, Clkp4, Clkp5, Clkp6, Clkp7, Clkp8, Clkp9, Clkp10, Clkp11, Clkp12, Clkp13, Clkp14, Clkp15, Clkp16, Clkp1, and Clkp2. That is, the first clock signal terminal CLK1 of the first stage of shift register unit GOA1<1> receives the third wide clock signal Clkp3; the first clock signal terminal CLK1 of the second stage of shift register unit GOA1<2> receives the next clock signal shifted relative to the third wide clock signal Clkp3, i.e. the fourth wide clock signal Clkp4, and so on until the first clock signal terminal CLK1 of the sixteenth stage of shift register unit GOA1<16> receives the next clock signal shifted relative to the first wide clock signal Clkp1, i.e. the second wide clock signal Clkp2.

Similarly, the second clock signal terminals CLK2 of the shift register units GOA1<1> to GOA1<16> respectively receive sixteen narrow clock signals sequentially shifted from the fourteenth narrow clock signal Clks14, i.e. Clks14, Clks15, Clks16, Clks1, Clks2, Clks3, Clks4, Clks5, Clks6, Clks7, Clks7, Clks8, Clks9, Clks10, Clks11, C1ks12, Clks13. The third clock signal terminals CLK3 of the shift register units GOA1<1> to GOA1<16> respectively receive sixteen wide clock signals sequentially shifted from the first wide clock signal Clkp1, that is, Clkp1 to Clkp16. The fourth clock signal terminals CLK4 of the shift register units GOA1<1> to GOA1<16> respectively receive sixteen narrow clock signals sequentially shifted from the first narrow clock signal Clks1, that is, Clks1 to Clks16.

The clock signal terminals of other sets of shift register units are coupled in the same method. For example, for the second set of shift register units GOA1<17> to GOA1<32>, the clock signal terminal of GOA1<17> is coupled in the same manner as that of the shift register unit GOA1<1>, the clock signal terminal of GOA1<18> coupled in the same manner as that of the shift register unit GOA1<2>, and so on. The other signal terminals of each shift register unit, such as the control signal terminal, power signal terminal, and reference signal terminal, may be coupled using the method described above with reference to FIG. 9A, and will not be repeated here.

Each shift register unit may provide the light-emitting control signal EM, the first gate driving signal G1, the second gate driving signal G2, and the third gate driving signal G3 required for the pixel circuit described above with reference to FIGS. 1 and 2 at the output signal terminals OUT1, OUT2, OUT3, and OUT4. Unlike that shown in FIGS. 9A and 9B, the compensation period is longer, which is described in detail below with reference to the signal timing shown in FIG. 12B.

FIG. 12B shows a signal timing diagram of the display driving circuit shown in FIG. 12A. As shown in FIG. 12B, the operating mode of each shift register unit in the display driving circuit is similar to the operating mode described above with reference to FIG. 9B, except that the shift register unit is controlled by different clock signals to generate different display driving signals. Detailed description will be made mainly on the differences in the following.

As shown in FIG. 12B, the display driving circuit receives sixteen sequentially shifted narrow clock signals Clks1 to Clks16 and sixteen sequentially shifted wide clock signals Clkp1 to Clkp16. The cycle of each of the narrow clock signals Clks1 to Clks16 is identical to the cycle of each of the wide clock signals Clkp1 to Clkp16, and the duty cycle of each of the narrow clock signals Clks1 to Clks16 is less than the duty cycle of each of the wide clock signals Clkp1 to Clkp16. As shown in FIG. 12B, the clock cycle of each of the narrow clock signals Clks1 to Clks16 and the clock cycle of each of the wide clock signals Clkp1 to Clkp16 are both 16H, and the valid level duration of each of the narrow clock signals Clks1 to Clks16 is 2H, and the valid level duration of each of the wide clock signals Clkp1 to Clkp16 is 11H.

Combining reference to FIG. 6, FIG. 12A, and FIG. 12B, taking n=1 as an example, the clock signal terminals CLK1 to CLK4 of the shift register unit GOA<1> receive the clock signals Clkp3, Clks14, Clkp1, and Clks1, respectively.

As shown in FIG. 12B, the operations performed by the shift register unit GOA<1>in the periods t1 to t7 are substantially the same as those in the periods t7 to t7 described above with reference to FIG. 9B, such that the first output unit 250_1 generates an output signal at the first output signal terminal OUT1 based on the clock signal Clkp3, the second output unit 250_2 generates an output signal at the output signal terminal OUT2 based on the clock signal Clks 14, the third output unit 250_3 generates an output signal at the output signal terminal OUT3 based on the clock signal Clkp1, and the fourth output unit 250_4 generates an output signal at the output signal terminal OUT4 based on the clock signal Clks1.

Other stages of shift register units operate in a similar method, such that each stage of shift register unit may provide multiple display driving signals required by the corresponding row of pixels. With reference to FIG. 12A, the first stage of shift register unit GOA<1> generates the light-emitting control signal EM<1>, the first gate driving signal G1<1>, and the second gate driving signal G2<1> for driving the first row of sub-pixels; the second stage of shift register unit GOA<2> generates the light-emitting control signal EM<2>, the first gate driving signal G1<2>, and the second gate driving signal G2<2> for driving the second row of sub-pixels, and so on.

As compared with FIG. 9B, the clock signal shown in FIG. 12B has a longer valid level duration, and the difference between the duty cycle of the wide clock signal and the duty cycle of the narrow clock signal shown in FIG. 12B is greater. In this way, the period T4 in which the threshold voltage compensation is performed is longer, for example, up to 9H, in the process of driving the sub-pixels to display based on the display driving signals output by the shift register unit. This is beneficial for further reducing the impact of threshold voltage on the output signal.

FIGS. 13A and 13B show a circuit diagram of a display driving circuit according to another embodiment of the present disclosure. The shift register unit in the display driving circuit may be implemented as the shift register unit of any of the above embodiments, such as the shift register unit described above with reference to FIG. 6. The display driving circuit shown in FIGS. 13A and 13B is similar to the display driving circuit shown in FIG. 9A, with a difference at least in that the fourth clock signal terminal CLK4 of each shift register unit is electrically coupled to the power signal terminal (second power signal terminal GVDD2). In addition, the coupling of the clock signal terminals, as well as the number of the clock signals and the waveforms of the clock signals shown in FIGS. 13A and 13B, are different from those shown in FIG. 9A. Detailed description will be made mainly on the differences in the following.

In the example shown in FIGS. 13A and 13B, K=4, i=1, and M=8. The display driving circuit receives eight sequentially shifted narrow clock signals Clks1 to Clks8 and eight sequentially shifted wide clock signals Clkp1 to Clkp8. N shift register units are divided into in sets of shift register units, each set of shift register units includes eight shift register units, for example, the first set of shift register units includes shift register units GOA1<1> to GOA1<8>, the second set of shift register units includes shift register units GOA1<9> to GOA1<16>, and so on. Each shift register unit includes four clock signal terminals CLK1 to CLK4 and four output signal terminals OUT1 to OUT4. Each shift register unit generates four output signals at the output signal terminals OUT1 to OUT4 based on the signals of the clock signal terminals CLK1 to CLK4, respectively.

As shown in FIG. 13A, in the first set of shift register units, the first clock signal terminals CLK1 of the first to eighth stages of shift register units GOA1<1> to GOA1<8> respectively receive eight wide clock signals sequentially shifted from the second wide clock signal Clkp2, i.e. Clkp2, Clkp3, Clkp4, Clkp5, Clkp6, Clkp7, Clkp8, Clkp1. Similarly, the second clock signal terminals CLK2 of the shift register units GOA1<1> to GOA1<8> respectively receive eight narrow clock signals sequentially shifted from the seventh narrow clock signal Clks7, i.e. Clks7, Clks8, Clks1, Clks2, Clks3, Clks4, Clks5, and Clks6. The third clock signal terminals CLK3 of the shift register units GOA1<1> to GOA1<8> respectively receive eight narrow clock signals sequentially shifted from the first narrow clock signal Clks1, i.e., Clks1 to Clks8. The fourth clock signal terminal CLK4 of each of the shift register units GOA1<1> to GOA1<8> is electrically coupled to the second power signal terminal GVDD2 of the shift register unit, which causes the fourth clock signal terminal CLK4 to receive the same signal as the second power signal terminal GVDD2, i.e. the second power signal Gvdd2.

The clock signal terminals of other sets of shift register units are coupled in the same method. For example, as shown in FIG. 13B, for the second set of shift register units GOA1<9> to GOA1<16>, the clock signal terminal of the shift register unit GOA1<9> is coupled in the same manner as that of the shift register unit GOA1<1>, and the clock signal terminal of the shift register unit GOA1<10> is coupled in the same manner as that of the shift register unit GOA1<2>, and so on. The other signal terminals of each shift register unit, such as the control signal terminal, power signal terminal, and reference signal terminal, may receive corresponding signals in the manner as described above with reference to FIG. 9A, which will not be repeated here.

The output signals of the four output terminals OUT1 to OUT4 of each stage of shift register unit may be used as the light-emitting control signal EM, the first gate driving signal G1, the second gate driving signal G2, and the third gate driving signal G3 required for the pixel circuit 10B described above. Unlike that shown in FIG. 9A, some of the output signals of one shift register unit and some of the output signals of another shift register unit form all the display driving signals required for a single sub-pixel, which is described in detail below with reference to FIG. 13C.

FIG. 13C shows a signal timing diagram of the display driving circuit shown in FIGS. 13A and 13B.

As shown in FIG. 13C, each shift register unit in the display driving circuit is operated in a similar manner as that described above with reference to FIG. 9B, with a difference at least in that two shift register units cooperate with each other to provide display driving signals to the same row of sub-pixels. Detailed description will be made mainly on the differences in the following.

As shown in FIG. 13C, the display driving circuit receives eight sequentially shifted narrow clock signals Clks1 to Clks8 and eight sequentially shifted wide clock signals Clkp1 to Clkp8. The narrow clock signals Clks1 to Clks8 have a cycle identical to that of the wide clock signals Clkp1 to Clkp8, and a duty cycle is less than that of the wide clock signals Clkp1 to Clkp8. As shown in FIG. 13C, both the narrow clock signals Clks1 to Clks8 and the wide clock signals Clkp1 to Clkp8 have a cycle of 16H. The narrow clock signals Clks1 to Clks16 have a valid level duration of 1.5H, and the wide clock signals Clkp1 to Clkp16 have a valid level duration of 9H. The shift of adjacent clock signals is 2H.

Taking n=9 as an example, combining reference to FIGS. 6, 13A, and 13B, the n^{th} stage of shift register unit GOA<9> is coupled in the same manner as the shift register unit GOA<1>, that is, the clock signal terminals CLK1 to CLK4 of the n^{th} stage of shift register unit GOA<9> receive clock signals Clkp2, Clks7, Clks1, and the second power signal Gvdd2, respectively, the first control signal terminal CKA of the n^{th} stage of shift register unit GOA<9> receives the first control signal Clka, and the second control signal terminal CKB of the n^{th} stage of shift register unit GOA<9> receives the second control signal Clkb.

As shown in FIG. 13B, in a period t1, the signal (i.e. CR<8>) of the cascaded output terminal of the previous stage of shift register unit received by the input signal terminal IN of the shift register unit GOA<9> shown in FIG. 13A is at high level. In this period, due to the first control signal Clka received by the first control signal terminal CKA of the shift register unit GOA<9> being at low level, the transistor T14 is in OFF state. The pull-up node Q is kept at low level, so that the transistor T3, as well as the transistors T1_1, T1_2, T1_3, and T1_4, are in OFF state. The cascaded output terminal CR and the output signal terminals OUT1 to OUT4 are kept at their previous potentials.

In a period t2, the first control signal Cka received by the first control signal terminal CKA of the shift register unit GOA<9> is at high level. Referring to FIG. 6, the high level of the first control signal terminal CKA causes the transistors T14 and T15 to be turned on, so that the high level of the input signal terminal IN is provided to the pull-up node Q and the node QH. The high level of the node QH causes the transistor T13 to be turned on, so that the pull-down node QB is pulled down to the low level of the first reference signal terminal VGL1. The high level of the pull-up node Q causes the transistor T3 to be turned on, so that the high level of the first power signal terminal GVDD1 is provided to the cascaded output terminal CR. The high level of the pull-up node Q also causes the transistors T1_1, T1_2, T1_3, and T1_4 to be turned on. At this point, due to the clock signals Clkp2, Clks7, and Clks1 received by the clock signal terminals CLK1 to CLK3 of the shift register unit GOA<9> being at low level, the output signal terminals OUT1 to OUT3 are at low level, and due to the second power signal Gvdd2 received by the clock signal terminal CLK4 of the shift register unit GOA<9> being at high level, the output signal terminal OUT4 is at high level.

In periods t3 to t5, the pull-up node Q is kept at high level, so that the transistors T1_1, T1_2, T1_3, and T1_4 in the shift register unit GOA<9> are in ON state, thereby providing Clkp2, Clks7, Clks1, and Gvdd2 to the output signal terminals OUT1 and OUT4, respectively.

In a period t6, the first control signal Clka received by the first control signal terminal CKA of the shift register unit GOA<9> is at high level, and the input signal terminal IN is at low level. Referring to FIG. 6, the transistors T14 and T15 are turned on, and the low level of input signal terminal IN is provided to the pull-up node Q and the node QH. The high level of the first control signal terminal CKA also causes the transistor T10 to be turned on, thereby providing the high level of the first control signal terminal CKA to the pull-down node QB. The high level of the pull-down node QB causes the transistor T4, as well as the transistors T2_1, T2_2, T2_3, and T2_4, to be turned on, resulting in low level output at the cascaded output terminal CR as well as output signal terminals OUT2, OUT3, and OUT4, and high level output at the output signal terminal OUT1.

At this point, the shift register unit GOA<9> has completed the output of the display driving signal.

Other stages of shift register units operate in a similar method, thereby generating output signals at their respective four output terminals OUT1 to OUT4.

The output signals of the four output terminals OUT1 to OUT4 of each stage of shift register unit may serve as the light-emitting control signal EM, the first gate driving signal G1, the third gate driving signal G3, and the second gate driving signal G2, respectively. Some of the output signals of one shift register unit and some of the output signals of another shift register unit may form the display driving signals required for a single sub-pixel. For example, the signals output from the output signal terminals OUT1 to OUT3 of the n^{th} stage of shift register unit GOA<n> may be respectively used as the light-emitting control signal EM<n−2>, the first gate driving signal G1<n−2>, and the third gate driving signal G3<n−2> to drive the (n−2)^{th} row of sub-pixels. The signal output from the output signal terminal OUT4 of the (n−2)^{th} stage of shift register unit GOA<n−2> may be used as the second gate driving signal G2<n−2> to drive the (n−2)^{th} row of sub-pixels. As shown in FIGS. 13A and 13B, the shift register units GOA<1> and GOA<3> provide the required display driving signals for the first row of sub-pixels. Specifically, the output signal of the output signal terminal OUT4 of the shift register unit GOA<1> is used as the second gate driving signal G2<1> for driving the first row of sub-pixels, and the output signals of the output signal terminals OUT1 to OUT3 of the shift register unit GOA<3> are respectively used as the light-emitting control signal EM<1>, the first gate driving signal G1<1>, and the third gate driving signal G3<1> for driving the first row of sub-pixels. Similarly, the output signal of the output signal terminal OUT4 of the shift register unit GOA<2> and the output signals of the output signal terminals OUT1 to OUT3 of the shift register unit GOA<4> serve as the second gate driving signal G2<2>, the light-emitting control signal EM<2>, the first gate driving signal G1<2>, and the third gate driving signal G3<2> for driving the second row of sub-pixels, and so on. The output signal terminals OUT1 to OUT3 of the first stage of shift register unit GOA<1> and the second stage of shift register unit GOA<2> may be set to be Dummy, that is, not coupled to any sub-pixel.

Embodiments of the present disclosure further provide a method for controlling a shift register unit, which is applicable to any of the shift register units in the above embodiments. This method may include an input phase, an output phase, and a reset phase.

In the input phase, the input circuit inputs the signal of the input signal terminal at first level to the pull-up node. In the output phase, the pull-down circuit pulls down the potential of the pull-down node based on the potential of the pull-up node, the cascaded output circuit provides a signal of the power signal terminal to the cascaded output terminal based on the potential of the pull-up node and the potential of the pull-down node, and each of the K output units of the signal output circuit provides the signal of the clock signal terminal coupled to the each of the K output units to the output signal terminal coupled to the each of the K output units based on the potential of the pull-up node and the potential of the pull-down node. In the reset phase, the input circuit inputs the signal of the input signal terminal at second level to the pull-up node, the pull-up circuit pulls up the potential of the pull-down node based on the potential of the input signal terminal, the cascaded output circuit provides a signal of the reference signal terminal to the cascaded output terminal based on the potential of the pull-up node and the potential of the pull-down node, and each of the K output units of the signal output circuit provides the signal of the power signal terminal or the reference signal terminal coupled to the each of the K output units to the output signal terminal coupled to the each of the K output units.

Taking the various embodiments described above with reference to FIGS. 9A to 12B as examples, the input phase may include the period t1, the output phase may include the periods t2 to t6, and the reset phase may include the period t7. Taking the embodiment described above with reference to FIGS. 13A to 13C as an example, the input phase may include the period t1, the output phase may include the periods t2 to t5, and the reset phase may include the period t6. The first level described above may be high level, and the second level may be low level.

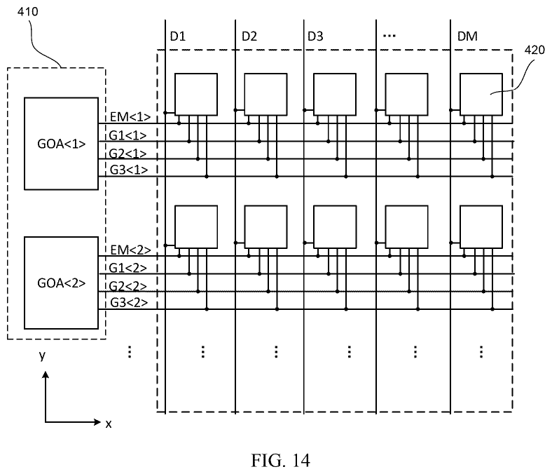

FIG. 14 shows a schematic diagram of a display panel according to an embodiment of the present disclosure.

As shown in FIG. 14, the display panel includes a display driving circuit 410 and a plurality of sub-pixels 420 arranged in an array. The display driving circuit 410 may be the display driving circuit of any of the above embodiments, such as the display driving circuits described above with reference to FIGS. 9A to 12B.

The K output signal terminals of the n^{th} stage of shift register unit in the display driving circuit 410 are coupled to the n^{th} row of sub-pixels to provide the required K display driving signals to the n^{th} row of sub-pixels. Assuming that the display driving circuit 410 is implemented by the display driving circuit described above with reference to FIGS. 9A and 9B, as shown in FIG. 14, the four output signal terminals of the first stage of shift register unit GOA<1> are coupled to the first row of sub-pixels through four signal lines, respectively, so as to provide the first gate driving signal G1<1>, the second gate driving signal G2<1>, the third gate driving signal G3<1>, and the light-emitting control signal EM<1> to the first row of sub-pixels. The four output signal terminals of the second stage of shift register unit GOA<2> are coupled to the second row of sub-pixels so as to provide the first gate driving signal G1<2>, the second gate driving signal G2<2>, the third gate driving signal G3<2>, and the light-emitting control signal EM<2> to the second row of sub-pixels, and so on. However, embodiments of the present disclosure are not limited to this, and different display driving circuits may be provided as desired. For example, in a case that the sub-pixel 420 has the circuit structure of the pixel circuit 10B described above, the display driving circuit 410 may be implemented as the display driving circuit described above with reference to FIGS. 10A and 10B, with each stage of shift register unit providing the first light-emitting control signal EM1, the second light-emitting control signal EM2, the first gate driving signal G1, and the second gate driving signal G2 to a corresponding row of sub-pixels. For another example, in a case that the sub-pixel 420 has the circuit structure of pixel circuit 10C as described above, the display driving circuit 410 may be implemented as the display driving circuit described above with reference to FIGS. 11A and 11B, and so on.

The plurality of sub-pixels 420 receive data signals through a plurality of data signal lines D1 to DM. Each row of sub-pixels 420 emits light based on the received data signals under control of the display driving signals output by the display driving circuit 410, thereby achieving image display.

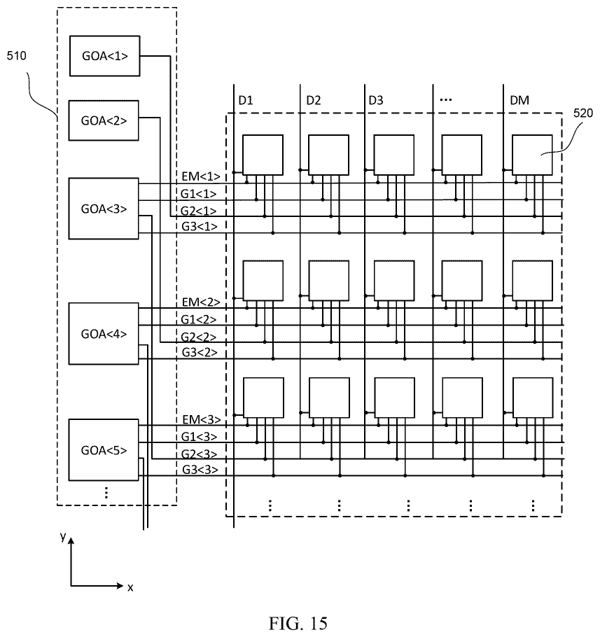

FIG. 15 shows a schematic diagram of a display panel according to another embodiment of the present disclosure. Unlike that shown in FIG. 14, the K1 output signal terminals of the n^{th} stage of shift register unit and the K2 output signal terminals of the (n+j)^{th} stage of shift register unit are coupled to the n^{th} row of sub-pixels to provide K display driving signals to the n^{th} row of sub-pixels, where K1+K2=K, and j is an integer greater than 1.

As shown in FIG. 15, the display panel includes a display driving circuit 510 and a plurality of sub-pixels 520 arranged in an array. The display driving circuit 510 may be the display driving circuit of any of the above embodiments, such as the display driving circuit described above with reference to FIGS. 13A to 13C. In this case, j=2, K1=1, K2=3. Combining reference to FIG. 13A and FIG. 13B, one output terminal of the first stage of shift register unit GOA<1>and three output terminals of the third stage of shift register unit GOA<3>are coupled to the first row of sub-pixels so as to provide display driving signals EM1<1>, G1<1>, G2<1>, and G3<1> to the first row of sub-pixels. Specifically, the fourth output signal terminal OUT4 of the shift register unit GOA<1> is coupled to the first row of sub-pixels to provide the second gate driving signal G2<1> to the first row of sub-pixels. The output signal terminals OUT1 to OUT3 of the shift register unit GOA<3> are coupled to the first row of sub-pixels to provide the light-emitting control signal EM<1>, the first gate driving signal G1<1>, and the third gate driving signal G3<1> to the first row of sub-pixels. Similarly, the output signal terminal OUT4 of the second stage of shift register unit GOA<2> and the output signal terminals OUT1 to OUT3 of the fourth stage of shift register unit GOA<4> are coupled to the second row of sub-pixels to provide the second gate driving signal G2<2>, the light-emitting control signal EM<2>, the first gate driving signal G1<2>, and the third gate driving signal G3<2> for driving the second row of sub-pixels, and so on. The output signal terminals OUT1 to OUT3 of the first stage of shift register unit GOA<1> and the second stage of shift register unit GOA<2> may be set to be Dummy, that is, not coupled to any sub-pixel.

Those skilled in the art may understand that embodiments described above are exemplary, and those skilled in the art may improve them. The structures described in various embodiments may be freely combined without structural or principle conflicts.

After elaborating on the preferred embodiments of the present disclosure, those skilled in the art may clearly understand that various changes and approaches may be made without departing from the scope and spirit of the accompanying claims, and the present disclosure is not limited to the implementation methods of the exemplary embodiments cited in the specification.

1. A shift register unit, comprising:
an input circuit coupled to an input signal terminal of the shift register unit, and configured to input a signal of the input signal terminal to a pull-up node;
a pull-up circuit coupled to the input signal terminal and a pull-down node of the shift register unit, and configured to pull up a potential of the pull-down node based on a potential of the input signal terminal;
a pull-down circuit coupled to the pull-up node and the pull-down node, and configured to pull down the potential of the pull-down node based on a potential of the pull-up node;
a cascaded output circuit coupled to the pull-up node, the pull-down node, a power signal terminal of the shift register unit, a reference signal terminal of the shift register unit, and a cascaded output terminal of the shift register unit, and configured to provide a signal of one of the power signal terminal and the reference signal terminal to the cascaded output terminal under control of the pull-up node and the pull-down node; and
a signal output circuit coupled to K clock signal terminals of the shift register unit and K output signal terminals of the shift register unit, and configured to generate K driving signals for driving a sub-pixel, wherein signals output from at least two of the K output signal terminals have different duty cycles, and the K driving signals comprise a gate driving signal and a light-emitting control signal, and wherein K is an integer greater than 1,
wherein the signal output circuit comprises K output units, with a k^{th} output unit being coupled to the pull-up node, the pull-down node, a k^{th} clock signal terminal, and a k^{th} output signal terminal, where 1≤k≤K;
wherein at least one of the K output units is further coupled to the power signal terminal, and is configured to provide a signal of one of the power signal terminal and the clock signal terminal coupled to the at least one of the K output units to the output signal terminal coupled to the at least one of the K output units, under control of the pull-up node and the pull-down node; and
wherein at least another of the K output units is further coupled to the reference signal terminal, and is configured to provide a signal of one of the reference signal terminal and the clock signal terminal coupled to the at least another of the K output units to the output signal terminal coupled to the at least another of the K output units, under control of the pull-up node and the pull-down node.

2. The shift register unit according to claim 1, wherein each of the K output units comprises a first output sub-circuit and a second output sub-circuit, each of the first output sub-circuit and the second output sub-circuit has a control terminal, an input terminal, and an output terminal and is configured to provide a signal of the input terminal to the output terminal under control of the control terminal; and
wherein, for each of the K output units,
the control terminal of the first output sub-circuit is coupled to the pull-up node, the input terminal of the first output sub-circuit is coupled to the clock signal terminal corresponding to the output unit, and the output terminal of the first output sub-circuit is coupled to the output signal terminal corresponding to the output unit; and
the control terminal of the second output sub-circuit is coupled to the pull-down node, the input terminal of the second output sub-circuit is coupled to the power signal terminal or the reference signal terminal, and the output terminal of the second output sub-circuit is coupled to the output signal terminal corresponding to the output unit.

3. The shift register unit according to claim 1, wherein the first output sub-circuit comprises a first transistor and a first capacitor, a gate of the first transistor serves as the control terminal of the first output sub-circuit, a first electrode of the first transistor serves as the input terminal of the first output sub-circuit, and a second electrode of the first transistor serves as the output terminal of the first output sub-circuit, a first electrode of the first capacitor is coupled to the gate of the first transistor, and a second electrode of the first capacitor is coupled to the second electrode of the first transistor; and
the second output sub-circuit comprises a second transistor, a gate of the second transistor serves as the control terminal of the second output sub-circuit, a first electrode of the second transistor serves as the input terminal of the second output sub-circuit, and a second electrode of the second transistor serves as the output terminal of the second output sub-circuit.

4. The shift register unit according to claim 1, wherein one of the K clock signal terminals is electrically coupled to the power signal terminal.

5. The shift register unit according to claim 1, wherein the cascaded output circuit comprises:
a first cascaded sub-circuit coupled to the pull-up node, the power signal terminal, and the cascaded output terminal, and configured to provide a signal of the power signal terminal to the cascaded output terminal under control of the pull-up node; and
a second cascaded sub-circuit coupled to the pull-down node, the reference signal terminal, and the cascaded output terminal, and configured to provide a signal of the reference signal terminal to the cascaded output terminal under control of the pull-down node.

6. The shift register unit according to claim 5, wherein the first cascaded sub-circuit comprises a third transistor and a second capacitor, a gate of the third transistor is coupled to the pull-up node, a first electrode of the third transistor is coupled to the power signal terminal, a second electrode of the third transistor is coupled to the cascaded output terminal, a first electrode of the second capacitor is coupled to the gate of the third transistor, and a second electrode of the second capacitor is coupled to the second electrode of the third transistor; and
the second cascaded sub-circuit comprises a fourth transistor and a third capacitor, a gate of the fourth transistor is coupled to the pull-down node, a first electrode of the fourth transistor is coupled to the reference signal terminal, a second electrode of the fourth transistor is coupled to the cascaded output terminal, a first electrode of the third capacitor is coupled to the gate of the fourth transistor, and a second electrode of the third capacitor is coupled to the second electrode of the fourth transistor.

7. The shift register unit according to claim 6, wherein the second cascaded sub-circuit further comprises a fifth transistor and a sixth transistor,
the second electrode of the fourth transistor is coupled to the cascaded output terminal through the fifth transistor, wherein a first electrode of the fifth transistor is coupled to the second electrode of the fourth transistor, a second electrode of the fifth transistor is coupled to the cascaded output terminal, and a gate of the fifth transistor is coupled to the pull-down node; and
a gate of the sixth transistor is coupled to the cascaded output terminal, a first electrode of the sixth transistor is coupled to the power signal terminal, and a second electrode of the sixth transistor is coupled to the pull-up node.

8. The shift register unit according to claim 1, wherein the power signal terminal comprises a first power signal terminal and a second power signal terminal, and the reference signal terminal comprises a first reference signal terminal and a second reference signal terminal; and
wherein the cascaded output circuit is coupled to the first power signal terminal and the first reference signal terminal, and the signal output circuit is coupled to the second power signal terminal and the second reference signal terminal.

9. The shift register unit according to claim 1, wherein the pull-up circuit comprises:
a first control sub-circuit coupled to the input signal terminal, the power signal terminal, a second control signal terminal of the shift register unit and an intermediate node of the shift register unit, and configured to control a potential of the intermediate node based on the signal of the input signal terminal and a signal of the second control signal terminal; and
a second control sub-circuit coupled to the intermediate node, the pull-down node, and a first control signal terminal of the shift register unit, and configured to pull up the potential of the pull-down node based on a signal of the intermediate node and a signal of the first control signal terminal.

10. The shift register unit according to claim 9, wherein the first control sub-circuit comprises a seventh transistor and an eighth transistor, a gate of the seventh transistor is coupled to the second control signal terminal, a first electrode of the seventh transistor is coupled to the power signal terminal, a second electrode of the seventh transistor is coupled to the intermediate node, a gate of the eighth transistor is coupled to the input signal terminal, a first electrode of the eighth transistor is coupled to the second control signal terminal, and a second electrode of the eighth transistor is coupled to the intermediate node; and
the second control sub-circuit comprises a ninth transistor, a tenth transistor and a fourth capacitor, a gate of the ninth transistor is coupled to the intermediate node, a first electrode of the ninth transistor is coupled to the first control signal terminal, a second electrode of the ninth transistor is coupled to a first electrode of the tenth transistor, a gate of the tenth transistor is coupled to the first control signal terminal, a second electrode of the tenth transistor is coupled to the pull-down node, a first electrode of the fourth capacitor is coupled to the gate of the ninth transistor, and a second electrode of the fourth capacitor is coupled to the second electrode of the ninth transistor.

11. The shift register unit according to claim 10, wherein the first control sub-circuit further comprises an eleventh transistor and a twelfth transistor,
the first electrode of the eighth transistor is coupled to the second control signal terminal through the eleventh transistor, wherein a gate of the eleventh transistor is coupled to the input signal terminal, a first electrode of the eleventh transistor is coupled to the second control signal terminal, and a second electrode of the eleventh transistor is coupled to the first electrode of the eighth transistor; and
a gate of the twelfth transistor is coupled to the intermediate node, a first electrode of the twelfth transistor is coupled to the power signal terminal, and a second electrode of the twelfth transistor is coupled to the first electrode of the eighth transistor.

12. The shift register unit according to claim 1, wherein the pull-down circuit comprises a thirteenth transistor, a gate of the thirteenth transistor is coupled to the pull-up node, a first electrode of the thirteenth transistor is coupled to the reference signal terminal, and a second electrode of the thirteenth transistor is coupled to the pull-down node;
wherein the input circuit comprises a fourteenth transistor, a gate of the fourteenth transistor is coupled to a first control signal terminal of the shift register unit, a first electrode of the fourteenth transistor is coupled to the input signal terminal, and a second electrode of the fourteenth transistor is coupled to the pull-up node;
wherein the input circuit further comprises a fifteenth transistor, and the second electrode of the fourteenth transistor is coupled to the pull-up node through the fifteenth transistor, wherein a gate of the fifteenth transistor is coupled to the power signal terminal or the first control signal terminal, a first electrode of the fifteenth transistor is coupled to the second electrode of the fourteenth transistor, and a second electrode of the fifteenth transistor is coupled to the pull-up node.

13. (canceled)

14. (canceled)

15. The shift register unit according to claim 1, further comprising a reset circuit coupled to the pull-up node, the pull-down node, the power signal terminal, the reference signal terminal, and a reset signal terminal of the shift register unit, and configured to provide a signal of the reference signal terminal to the pull-up node and a signal of the power signal terminal to the pull-down node under control of the reset signal terminal;
wherein the reset circuit comprises a sixteenth transistor and a seventeenth transistor, a gate of the sixteenth transistor is coupled to the reset signal terminal, a first electrode of the sixteenth transistor is coupled to the reference signal terminal, and a second electrode of the sixteenth transistor is coupled to the pull-up node; and a gate of the seventeenth transistor is coupled to the reset signal terminal, a first electrode of the seventeenth transistor is coupled to the power signal terminal, and a second electrode of the seventeenth transistor is coupled to the pull-down node;
wherein the reset circuit further comprises an eighteenth transistor, and the first electrode of the sixteenth transistor is coupled to the reference signal terminal through the eighteenth transistor, wherein a gate of the eighteenth transistor is coupled to the reset signal terminal, a first electrode of the eighteenth transistor is coupled to the reference signal terminal, and a second electrode of the eighteenth transistor is coupled to the first electrode of the sixteenth transistor;
wherein the signal output circuit is configured to generate some or all of the K driving signals for driving a single sub-pixel.

16. (canceled)

17. (canceled)

18. The shift register unit according to claim 1, wherein K=4,
for one or two of the K output units, the output unit is configured to provide a signal of one of the power signal terminal and the clock signal terminal coupled to the output unit to the output signal terminal coupled to the output unit under control of the pull-up node and the pull-down node; and
for others of the K output units, the output unit is configured to provide a signal of one of the reference signal terminal and the clock signal terminal coupled to the output unit to the output signal terminal coupled to the output unit under control of the pull-up node and the pull-down node. ; or
wherein K=3, for one of the K output units, the output unit is configured to provide a signal of one of the power signal terminal and the clock signal terminal coupled to the output unit to the output signal terminal coupled to the output unit under control of the pull-up node and the pull-down node, and for others of the K output units, the output unit is configured to provide a signal of one of the reference signal terminal and the clock signal terminal coupled to the output unit to the output signal terminal coupled to the output unit under control of the pull-up node and the pull-down node.

19. (canceled)

20. (canceled)

21. A display driving circuit comprising N cascaded shift register units, wherein the shift register unit is the shift register unit according to claim 1, wherein a cascaded output terminal of an n^{th} stage of shift register unit is coupled to an input signal terminal of an (n+i)^{th} stage of shift register unit, where N, n, and i are positive integers, and n<N.

22. The display driving circuit according to claim 21, wherein the display driving circuit is configured to receive M narrow clock signals and M wide clock signals, a cycle of each of the M narrow clock signals is identical to a cycle of each of the M wide clock signals, and a duty cycle of each of the M narrow clock signals is less than a duty cycle of each of the M wide clock signal, where a ratio of M to K is a positive integer; and
the N shift register units are divided into at least one set of shift register units, each set of shift register units comprises M cascaded shift register units, and M k1^{th} clock signal terminals of each set of shift register units are configured to receive the M narrow clock signals respectively, and M k2^{th} clock signal terminals of each set of shift register units are configured to receive the M wide clock signals respectively, where k1 and k2 are positive integers, 1≤k1≤N, 1≤k2≤N, and k 1 ≠k2.

23. The display driving circuit according to claim 22, wherein K=4, i=1, M=4; first clock signal terminals of first to fourth stages of shift register units in each set of shift register units are configured to receive a second narrow clock signal, a third narrow clock signal, a fourth narrow clock signal, and a first narrow clock signal, respectively; second clock signal terminals of the first to fourth stages of shift register units in each set of shift register units are configured to receive the first narrow clock signal, the second narrow clock signal, the third narrow clock signal, and the fourth narrow clock signal, respectively; third clock signal terminals of the first to fourth stages of shift register units in each set of shift register units are configured to receive a first wide clock signal, a second wide clock signal, a third wide clock signal, and a fourth wide clock signal, respectively; and fourth clock signal terminals of the first to fourth stages of shift register units in each set of shift register units are configured to receive the third narrow clock signal, the fourth narrow clock signal, the first narrow clock signal, and the second narrow clock signal, respectively; or
wherein K=4, i=1, M=4; first clock signal terminals of first to fourth stages of shift register units in each set of shift register units are configured to receive a fourth wide clock signal, a first wide clock signal, a second wide clock signal, and a third wide clock signal, respectively; second clock signal terminals of the first to fourth stages of shift register units in each set of shift register units are configured to receive the second wide clock signal, the third wide clock signal, the fourth wide clock signal, and the first wide clock signal, respectively; third clock signal terminals of the first to fourth stages of shift register units in each set of shift register units are configured to receive the first wide clock signal, the second wide clock signal, the third wide clock signal, and the fourth wide clock signal, respectively; and fourth clock signal terminals of the first to fourth stages of shift register units in each set of shift register units are configured to receive a third narrow clock signal, a fourth narrow clock signal, a first narrow clock signal, and a second narrow clock signal, respectively; or
wherein K=3, i=1, M=4; first clock signal terminals of first to fourth stages of shift register units in each set of shift register units are configured to receive a third narrow clock signal, a fourth narrow clock signal, a first narrow clock signal, and a second narrow clock signal, respectively; second clock signal terminals of the first to fourth stages of shift register units in each set of shift register units are configured to receive a second wide clock signal, a third wide clock signal, a fourth wide clock signal, and a first wide clock signal, respectively; and third clock signal terminals of the first to fourth stages of shift register units in each set of shift register units are configured to receive the second narrow clock signal, the third narrow clock signal, the fourth narrow clock signal, and the first narrow clock signal, respectively; or
wherein K=4, i=1, M=8; first clock signal terminals of first to eighth stages of shift register units in each set of shift register units are configured to receive eight wide clock signals sequentially shifted from a second wide clock signal, respectively; second clock signal terminals of the first to eighth stages of shift register units in each set of shift register units are configured to receive eight narrow clock signals sequentially shifted from a seventh narrow clock signal, respectively; third clock signal terminals of the first to eighth stages of shift register units in each set of shift register units are configured to receive eight narrow clock signals sequentially shifted from a first narrow clock signal, respectively; and fourth clock signal terminals of the first to eighth stages of shift register units in each set of shift register units are electrically coupled to the power signal terminal and configured to receive a power signal of the power signal terminal; or
wherein K=4, i=1, M=16; first clock signal terminals of first to sixteenth stages of shift register units in each set of shift register units are configured to receive sixteen wide clock signals sequentially shifted from a third wide clock signal, respectively; and second clock signal terminals of the first to sixteenth stages of shift register units in each set of shift register units are configured to receive sixteen narrow clock signals sequentially shifted from a fourteenth narrow clock signal, respectively; third clock signal terminals of the first to sixteenth stages of shift register units in each set of shift register units are configured to receive sixteen wide clock signals sequentially shifted from a first wide clock signal, respectively; and
fourth clock signal terminals of the first to sixteenth stages of shift register units in each set of shift register units are configured to receive sixteen narrow clock signals sequentially shifted from a first narrow clock signal.

24. (canceled)

25. (canceled)

26. (canceled)

27. (canceled)

28. A display panel comprising a display driving circuit according to claim 21 and a plurality of sub-pixels arranged in an array, wherein the display driving circuit is coupled to the plurality of sub-pixels to provide display driving signals to the plurality of sub-pixels.

29. The display panel according to claim 28, wherein K output signal terminals of an n^{th} stage of shift register unit are coupled to an n^{th} row of sub-pixels to provide K display driving signals to the n^{th} row of sub-pixels, and the K display driving signals comprise a gate driving signal and a light-emitting control signal for driving the n^{th} row of sub-pixels; or
wherein K1 output signal terminals of an n^{th} stage of shift register unit and K2 output signal terminals of an (n+j)^{th} stage of shift register unit are coupled to an n^{th} row of sub-pixels to provide K display driving signals to the n^{th} row of sub-pixels, where K1+K2=K, and j is an integer greater than 1.

30. (canceled)

31. A method for controlling a shift register unit, the shift register unit comprising: an input circuit coupled to an input signal terminal of the shift register unit, and configured to input a signal of the input signal terminal to a pull-up node; a pull-up circuit coupled to the input signal terminal and a pull-down node of the shift register unit, and configured to pull up a potential of the pull-down node based on a potential of the input signal terminal; a pull-down circuit coupled to the pull-up node and the pull-down node, and configured to pull down the potential of the pull-down node based on a potential of the pull-up node; a cascaded output circuit coupled to the pull-up node, the pull-down node, a power signal terminal of the shift register unit, a reference signal terminal of the shift register unit, and a cascaded output terminal of the shift register unit, and configured to provide a signal of one of the power signal terminal and the reference signal terminal to the cascaded output terminal under control of the pull-up node and the pull-down node; and a signal output circuit coupled to K clock signal terminals of the shift register unit and K output signal terminals of the shift register unit, and configured to generate K driving signals for driving a sub-pixel, wherein signals output from at least two of the K output signal terminals have different duty cycles, and the K driving signals comprise a gate driving signal and a light-emitting control signal, and wherein K is an integer greater than 1, wherein the signal output circuit comprises K output units, with a k^{th} output unit being coupled to the pull-up node, the pull-down node, a k^{th} clock signal terminal, and a k^{th} output signal terminal, where 1<k<K; wherein at least one of the K output units is further coupled to the power signal terminal, and is configured to provide a signal of one of the power signal terminal and the clock signal terminal coupled to the at least one of the K output units to the output signal terminal coupled to the at least one of the K output units, under control of the pull-up node and the pull-down node; and wherein at least another of the K output units is further coupled to the reference signal terminal, and is configured to provide a signal of one of the reference signal terminal and the clock signal terminal coupled to the at least another of the K output units to the output signal terminal coupled to the at least another of the K output units, under control of the pull-up node and the pull-down node;
the method comprising:
in an input phase, inputting, by the input circuit, the signal of the input signal terminal at first level to the pull-up node;
in an output phase, pulling down the potential of the pull-down node by the pull-down circuit based on the potential of the pull-up node, providing a signal of the power signal terminal to the cascaded output terminal by the cascaded output circuit based on the potential of the pull-up node and the potential of the pull-down node, and providing, by each of the K output units of the signal output circuit, the signal of the clock signal terminal coupled to the each of the K output units to the output signal terminal coupled to the each of the K output units based on the potential of the pull-up node and the potential of the pull-down node; and
in a reset phase, inputting the signal of the input signal terminal at second level to the pull-up node by the input circuit, pulling up the potential of the pull-down node by the pull-up circuit based on the potential of the input signal terminal, providing a signal of the reference signal terminal to the cascaded output terminal by the cascaded output circuit based on the potential of the pull-up node and the potential of the pull-down node, and providing, by each of the K output units of the signal output circuit, the signal of the power signal terminal or the reference signal terminal coupled to the each of the K output units to the output signal terminal coupled to the each of the K output units.
